(19) United States
(12) Patent Application Publication
(10) Pub. No.: US 2026/0082581 A1
(43) Pub. Date: Mar. 19, 2026

(54) SEMICONDUCTOR DEVICE AND DATA STORAGE SYSTEM INCLUDING THE SAME

(71) Applicant: SAMSUNG ELECTRONICS CO., LTD., Suwon-si (KR)

(72) Inventors: Dongoh Kim, Suwon-si (KR); Woo Young Choi, Seoul (KR); Kiseok Lee, Suwon-si (KR); Changha Kim, Seoul (KR)

(73) Assignee: SAMSUNG ELECTRONICS CO., LTD., Suwon-si (KR)

(21) Appl. No.: 19/096,972

(22) Filed: Apr. 1, 2025

(30) Foreign Application Priority Data
Sep. 13, 2024 (KR) 10-2024-0125611

(51) Int. Cl. H10B 53/20; H10B 53/10; H10B 53/30

(52) U.S. Cl. CPC H10B 53/20; H10B 53/10; H10B 53/30

(57) ABSTRACT

A semiconductor device includes: a substrate; stack structures including interlayer insulating layers and horizontal electrodes alternately stacked in a vertical direction on the substrate; a vertical pillar spaced apart from the substrate and provided in a hole penetrating through the stack structure; and protrusion portions provided between the vertical pillar and the horizontal electrodes, and spaced apart from each other in the vertical direction, and the vertical pillar includes: a conductive pillar in the hole; a first information storage layer covering a side surface and a bottom surface of the conductive pillar and including a ferroelectric layer; and an interface insulating layer covering an outer surface of the first information storage layer, and each of the protrusion portions includes a conductive layer disposed between the interface insulating layer and the horizontal electrodes.

### CROSS-REFERENCE TO RELATED APPLICATION

This application claims priority to Korean Patent Application No. 10-2024-0125611, filed on Sep. 13, 2024, in the Korean Intellectual Property Office, the disclosure of which is incorporated by reference herein in its entirety.

### BACKGROUND

The present disclosure relates to semiconductor device and data storage system including the same.

In electronic systems requiring data storage, semiconductor devices capable of storing large amounts of data are in demand. Accordingly, methods of increasing the data storage capacity of semiconductor devices have been researched. For example, as one of the methods of increasing the data storage capacity of semiconductor devices, a semiconductor device including memory cells arranged three-dimensionally, instead of two-dimensionally, has been proposed.

### SUMMARY

One or more example embodiments provide a semiconductor device to which a ferroelectric layer capable of storing information by utilizing a polarization state is applied.

One or more example embodiments provide a semiconductor device and a data storage system including the semiconductor device.

According to an aspect of an example embodiment, a semiconductor device includes: stack structures including interlayer insulating layers and horizontal electrodes alternately stacked on a substrate in a vertical direction, the stack structures extending in a first direction, perpendicular to the vertical direction, and spaced apart from each other in a second direction, perpendicular to the first direction; a molded structure including the interlayer insulating layers and sacrificial insulating layers alternately stacked on the substrate in the vertical direction, the molded structure extending in the first direction between the stack structures; vertical pillars provided in holes penetrating through the stack structures and the molded structure at boundaries between the stack structures and the molded structure, and spaced apart from the substrate; and protrusion portions provided between each of the vertical pillars and the horizontal electrodes, and spaced apart from each other in the vertical direction. Each of the vertical pillars includes: a conductive pillar provided in a hole; a first information storage layer covering a side surface and a bottom surface of the conductive pillar, and including a ferroelectric layer; and an interface insulating layer covering an outer surface of the first information storage layer. Each of the protrusion portions includes a conductive layer in which a portion of an outer surface of the conductive layer is in contact with one of the horizontal electrodes, and a remainder of the outer surface of the conductive layer is in contact with one of the sacrificial insulating layers.

According to another aspect of an example embodiment, a semiconductor device includes: a stack structure including interlayer insulating layers and horizontal electrodes alternately stacked on a substrate in a vertical direction, the stack structure extending in a first direction, perpendicular to the vertical direction; a molded structure including the interlayer insulating layers and sacrificial insulating layers alternately stacked on the substrate in the vertical direction, and provided adjacent to the stack structure in a second direction, and extending in the first direction, the second direction being perpendicular to the vertical direction and the first direction; and vertical structures provided in holes penetrating through the stack structure and the molded structure at boundaries between the stack structure and the molded structure, and spaced apart from the substrate. Each of the vertical structures includes: a conductive pillar provided in a central region of each of the holes; a first information storage layer surrounding the conductive pillar, having a first thickness, and including a ferroelectric layer; an interface insulating layer surrounding the first information storage layer, having a second thickness less than the first thickness; and conductive layers surrounding the interface insulating layer between the interface insulating layer and the horizontal electrodes, the conductive layers being spaced apart from each other in the vertical direction.

According to another aspect of an example embodiment, a data storage system includes: a semiconductor device including an input/output pad; and a controller electrically connected to the semiconductor device through the input/output pad and configured to control the semiconductor device. The semiconductor device includes: stack structures including interlayer insulating layers and horizontal electrodes alternately stacked on a substrate in a vertical direction, the stack structures extending in a first direction, perpendicular to the vertical direction, and the stack structures being spaced apart from each other in a second direction, perpendicular to the first direction; a molded structure including the interlayer insulating layers and sacrificial insulating layers alternately stacked on the substrate in the vertical direction, and extending in the first direction between the stack structures; vertical pillars provided in holes penetrating through the stack structures and the molded structure, and spaced apart from the substrate; and protrusion portions provided between each of the vertical pillars and the horizontal electrodes at boundaries between the stack structures and the molded structure, and spaced apart from each other in the vertical direction. Each of the vertical pillars includes: a conductive pillar provided in a hole; a first information storage layer covering a side surface and a bottom surface of the conductive pillar, and including a ferroelectric layer; and an interface insulating layer covering an outer surface of the first information storage layer. Each of the protrusion portions includes a conductive layer in which a first portion of an outer surface of the conductive layer is in contact with one of the horizontal electrodes and a second portion of the outer surface of the conductive layer is in contact with one of the sacrificial insulating layers.

According to one or more example embodiments, a ferroelectric tunnel junction, a two-terminal element including, as an information storage structure, a ferroelectric layer capable of storing information using a polarization state, may be formed as a three-dimensional vertical structure to improve integration. The ferroelectric tunnel junction memory element may be formed in a circular type to increase an electric field applied to the ferroelectric layer, thereby increasing a memory window.

One or more example embodiments provide an optimal structure that may simplify interconnection lines while improving integration may be provided by forming a two-terminal ferroelectric tunnel junction element as a three-dimensional vertical structure.

Advantages and effects of the present application are not limited to the foregoing content.

### BRIEF DESCRIPTION OF DRAWINGS

The above and other aspects, features, and advantages will be more apparent from the following description of example embodiments, taken in conjunction with the accompanying drawings, in which:

FIG. 1 is a circuit diagram illustrating memory cells of a semiconductor device according to an example embodiment;

FIG. 2 is a plan view illustrating a semiconductor device according to example embodiments;

FIG. 3 and FIG. 4 are cross-sectional views of semiconductor devices according to example embodiments;

FIG. 5 is a partially enlarged cross-sectional view of a semiconductor device according to an example embodiment;

FIGS. 6 to 9 are partially enlarged cross-sectional views conceptually illustrating a modified example of a semiconductor device according to an example embodiment;

FIGS. 10 to 20 are plan views illustrating a modified example of a semiconductor device according to another example embodiment;

FIG. 21 is a cross-sectional view of a semiconductor device according to another example embodiment;

FIGS. 22A, 22B, 22C, 22D, 22E, 22F, 22G and 22H are conceptual views illustrating an exemplary example of a method of forming a semiconductor device according to an example embodiment;

FIG. 23 is a schematic diagram illustrating a data storage system including a semiconductor device according to an example embodiment; and

FIG. 24 is a perspective view schematically illustrating a data storage system including a semiconductor device according to an example embodiment.

### DETAILED DESCRIPTION

Hereinafter, example embodiments are described with reference to the accompanying drawings. Terms such as “upper,” “intermediate,” and “lower” may be replaced with other terms such as “first,” “second,” and “third” and may be used to describe components of the specification. The terms such as “first,” “second,” and “third” may be used to describe various components, but the components are not limited thereto, and the “first component” could be termed “second component.” Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

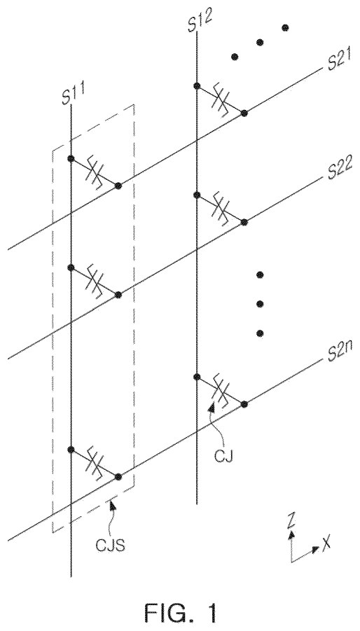

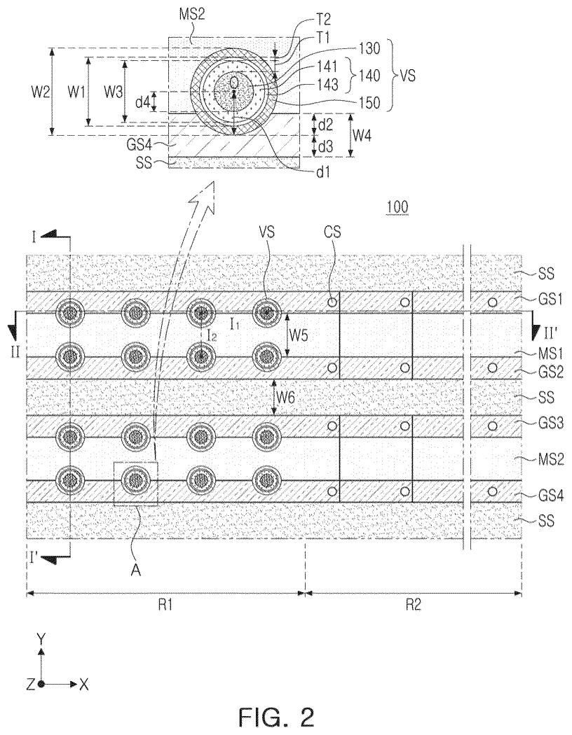

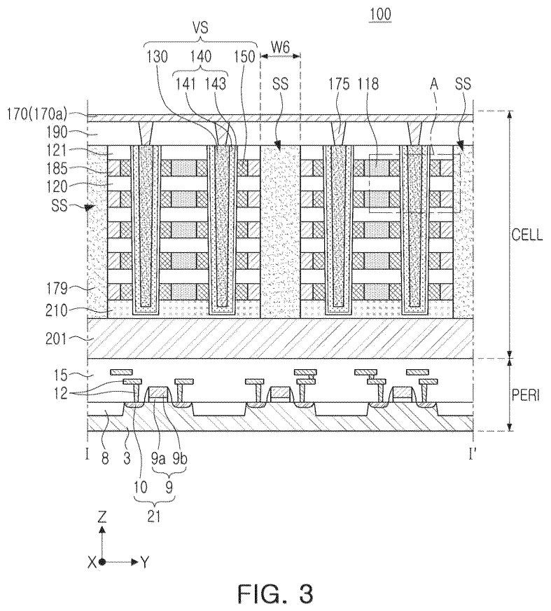

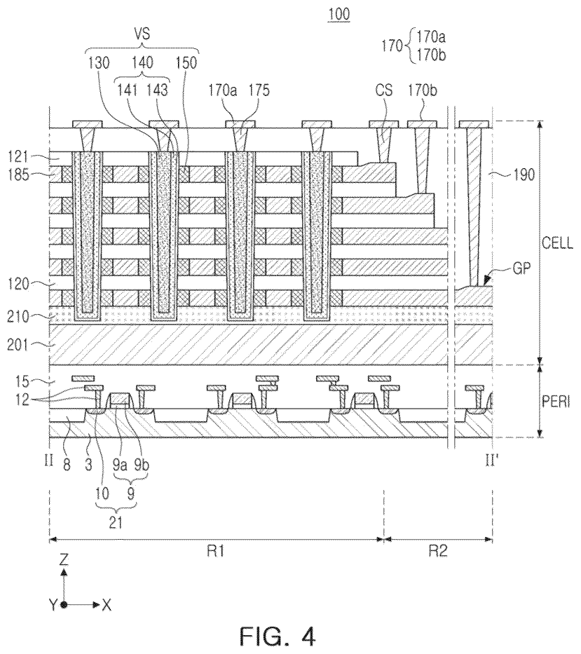

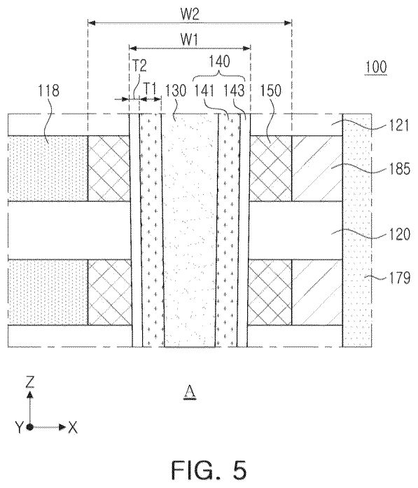

Referring to FIGS. 1 to 5, a semiconductor device according to an example embodiment will be described. FIG. 1 is a circuit diagram illustrating a memory cell of a semiconductor device according to an example embodiment, FIG. 2 is a plan view illustrating a semiconductor device according to example embodiments, FIG. 3 is a cross-sectional view taken along line I-I′ of the semiconductor device of FIG. 2, FIG. 4 is a cross-sectional view taken along line II-II′ of the semiconductor device of FIG. 2, and FIG. 5 is an enlarged cross-sectional view of region ‘A’ of FIG. 2.

Referring to FIG. 1, a semiconductor device 100 according to an example embodiment may include a plurality of memory cells CJ. The memory cells CJ may be arranged three-dimensionally in a Z-direction and an X-direction. The memory cells CJ may include a variable capacitor implementing a ferroelectric tunnel junction. Each of the memory cells CJ may include a dielectric structure between two conductive layers facing each other. One of the two conductive layers, a first conductive layer, may be connected to first signal lines (S11, S12, . . . ), and the other conductive layer, a second conductive layer, may be connected to second signal lines (S21, S22, . . . , S2n), respectively.

Each of the first signal lines (S11, S12, . . . ) may extend in the Z-direction and may simultaneously contact first conductive layers of one column of memory cells CJ. The second signal lines (S21, S22, . . . , S2n) may be stacked and spaced apart from each other in the Z-direction. Each of the second signal lines (S21, S22, . . . , S2n) may extend in the X-direction. The second signal lines (S21, S22, . . . , S2n) may simultaneously contact second conductive layers of one row of memory cells CJ. The first signal lines (S11, S12, . . . ) may be driven as bit lines, and the second signal lines (S21, S22, . . . , S2n) may be driven as word lines.

A unit memory cell CJ that contacts one of the first signal lines (S11, S12, . . . ) and contacts one of the second signal lines (S21, S22, . . . , S2n) may include an information storage structure as a dielectric structure between the first and second conductive layers, so that a polarization direction of a ferroelectric layer in the information storage structure may be changed according to a strength of an electric field between the first and second conductive layers, thus changing a tunneling current.

The Z-direction may be referred to and described as a first direction or a vertical direction. The X-direction may be perpendicular to the Z-direction and may be referred to and described as a second direction or a first horizontal direction. A Y-direction may be perpendicular to the Z-direction and the X-direction and may be referred to and described as a third direction or a second horizontal direction.

A plurality of memory cells CJ in one column aligned in the Z-direction may form a single memory cell string CJS, and may be referred to as a vertical structure VS of FIGS. 2 to 5.

Referring to FIGS. 1 to 5, in the vertical structure VS, the plurality of memory cells CJ spaced apart from each other in the Z-direction may include an information storage structure 140 between a first conductive layer 130 and a second conductive layer 150, and the information storage structure 140 may include a first information storage layer 141, which is a ferroelectric layer FEL, and an interface insulating layer 143.

The ferroelectric layer FEL may have a non-centrosymmetric charge distribution in each memory cell CJ and thus may have a spontaneous dipole (dipole (electric dipole)), i.e., spontaneous polarization. The ferroelectric layer FEL has a remanent polarization due to a dipole even in the absence of an external electric field. Additionally, the polarization direction may be switched by an external electric field.

In this regard, the ferroelectric layer FEL may have a positive or negative polarization state, and the polarization state may be changed by an electric field applied to the ferroelectric layer FEL during a program operation. The polarization state of the ferroelectric layer FEL may be maintained even when power is cut off, so that a semiconductor memory device may operate as a nonvolatile memory element. In example embodiments, the polarization state of the ferroelectric layer FEL may be determined by a voltage difference between the first conductive layer 130 and the second conductive layer 150.

For example, during a program operation, the polarity of the ferroelectric layer FEL may be changed by a difference between a program voltage applied to the second conductive layer 150 in the memory cell CJ and a ground voltage applied to the first conductive layer 130. A voltage difference between the program voltage and the ground voltage may be equal or to more than a minimum voltage required to change the polarization of the ferroelectric layer FEL, and, for example, may be a high voltage of 20 V or more, but example embodiments are not limited to the above-described range.

During a read operation in which data are read from the memory cell CJ, a tunneling current may change due to the changed polarity, and when a detection voltage is applied to the second conductive layer 150 of the selected memory cell CJ, the data stored in the memory cell CJ may be read by measuring a current flowing through the first conductive layer 130.

The semiconductor device 100 of an example embodiment may be implemented as a vertical structure VS, for example a three-dimensional element in which memory cell strings CJS disposed in the Z-direction of FIG. 1 extend in the Z-direction.

Referring to FIGS. 2 to 5, the semiconductor device 100 according to an example embodiment may include a first structure CELL and a second structure PERI. The first structure CELL may vertically overlap the second structure PERI.

In an example embodiment, the first structure CELL may be a memory region in which three-dimensionally arranged memory cells CJ are arranged, and the second structure PERI may be a peripheral circuit region.

In an example embodiment, the first structure CELL may be referred to as a memory chip structure or a first chip structure, and the second structure PERI may be referred to as a peripheral circuit structure or a second chip structure. In FIGS. 3 and 4, the first structure CELL is illustrated as being disposed on the second structure PERI, but example embodiments are not limited thereto, and the first structure CELL may be disposed below the second structure PERI.

The second structure PERI may include a first substrate 3, circuit elements 21, a lower interconnection structure 12, and a lower capping layer 15.

The first substrate 3 may include a semiconductor material, such as a group IV semiconductor, a group III-V compound semiconductor, or a group II-VI compound semiconductor. The first substrate 3 may be provided as a bulk wafer or an epitaxial layer. An active region may be defined by element isolating layers on the first substrate 3. Source/drain regions 10 including impurities may be disposed in a portion of the active region.

The circuit elements 21 may be on the first substrate 3. The circuit elements 21 may include a transistor. Each of the circuit elements 21 may include a circuit gate dielectric layer 9b, a circuit gate electrode 9a, and a source/drain region 10. The source/drain regions 10 including impurities may be disposed in the first substrate 3 on both sides of the circuit gate electrode 9a. Spacer layers may be disposed on both sides of the circuit gate electrode 9a. The circuit gate dielectric layer 9b may include silicon oxide, silicon nitride, or a high-K material. The circuit gate electrode 9a may include at least one of titanium nitride (TiN), tantalum nitride (TaN) and tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), or ruthenium (Ru). The circuit gate electrode 9a may include a semiconductor layer, for example, a doped polycrystalline silicon layer. According to an example embodiment, the circuit gate electrode 9a may be formed of two or more multilayers.

The lower interconnection structure 12 may be electrically connected to the circuit gate electrodes 9a and the source/drain regions 10 of the circuit elements 21. The lower interconnection structure 12 may include lower contact plugs having a cylindrical or truncated cone shape and lower interconnection lines in which at least one region has a line shape. Some of the lower contact plugs may be connected to the source/drain regions 10, and others of the lower contact plugs may be connected to the gate electrodes 9a. The lower contact plugs may electrically connect lower interconnection lines disposed on different levels from an upper surface of the first substrate 3 to each other. The lower interconnection structure 12 may include a conductive material, and may include, for example, tungsten (W), copper (Cu), and aluminum (Al), and each of the components may further include a diffusion barrier layer including at least one of titanium (Ti), titanium nitride (TiN), tantalum (Ta), tantalum nitride (TaN), or tungsten nitride (WN). According to example embodiments, the number of layers and the arrangement form of the lower contact plugs and lower interconnection lines included in the lower interconnection structure 12 may be variously changed.

The lower capping layer 15 may be disposed on the first substrate 3 to cover the circuit elements 21 and the lower interconnection structure 12. The lower capping layer 15 may include a plurality of insulating layers. The lower capping layer 15 may include an insulating material, for example, silicon oxide, silicon nitride, silicon oxynitride, or silicon oxycarbide.

The first structure CELL may include a cell region R1 and an extension region R2. The extension region R2 may be on one side of the cell region R1 in the X-direction.

The cell region R1 is a memory cell region in which the memory cell strings CJS are disposed, and may be a region in which the vertical structures VS are disposed. The extension region R2 may be a region in which a plurality of contact plugs CS connected to horizontal electrodes 185 on different levels are disposed.

The semiconductor device 100 may include a second substrate 201 in the cell region R1 and the extension region R2, stack structures GS1, GS2, GS3 and GS4, molded structures MS1 and MS2 extending in the X-direction on the second substrate 201 and disposed adjacently to each other in the Y-direction, and separation structures SS extending in the X-direction by penetrating through the stack structures GS1, GS2, GS3 and GS4.

The semiconductor device 100 may further include support structures in the extension region R2, and the cell region R1 and the extension region R2 may include a cell region insulating layer 190, and may include studs 175 and upper circuit interconnection lines 170 penetrating through the cell region insulating layer 190 and performing electrical connection with the vertical structure VS and the contact plugs CS. In FIG. 4, the contact plugs CS are illustrated as extending by different lengths for connection between each horizontal electrode 185 and the contact plugs CS, but the present disclosure is not limited thereto.

The second substrate 201 may include a semiconductor material, for example, a group IV semiconductor, a group III-V compound semiconductor, or a group II-VI compound semiconductor. For example, the group IV semiconductor may include silicon (Si), germanium (Ge), or silicon-germanium (SiGe). The second substrate 201 may be physically and electrically spaced apart from the vertical structures VS. For example, an upper surface of the second substrate 201 may be disposed in a position lower than a level of a lower end of the vertical structures VS.

An etching stop layer 210 may be disposed on the second substrate 201. The etching stop layer 210 may be disposed to cover an entire front surface of the second substrate 201, and may include an insulating material. The etching stop layer 210 may include an insulating material having an etching selectivity with an interlayer insulating layer 120 and sacrificial insulating layers 118 disposed in an upper portion, but example embodiments are not limited thereto and, for example, the etching stop layer 210 may be formed of the same material as that of the interlayer insulating layer 120 and may have a thickness greater than a thickness of the interlayer insulating layer 120.

The stack structures GS1, GS2, GS3 and GS4 may include horizontal electrodes 185 having an electrode width W4 in the Y-direction, extending in the X-direction, and stacked and spaced apart from each other in a vertical direction (Z-direction). The stack structures GS1, GS2, GS3 and GS4 may vertically overlap the second structure PERI, which may be a peripheral circuit structure. The stack structures GS1, GS2, GS3 and GS4 may have lower surfaces in contact with the etching stop layer 210 on the second substrate 201.

The stack structures GS1, GS2, GS3 and GS4 may be spaced apart from each other in the Y-direction, and separation distances therebetween may be different from each other. For example, separation distances when the molded structures MS1 and MS2 are disposed between the stack structures GS1, GS2, GS3 and GS4 may be greater than separation distance when the separation structure SS is disposed between the stack structures GS1, GS2, GS3 and GS4, but the present disclosure is not limited thereto.

The horizontal electrodes 185 may be vertically spaced apart from each other and stacked on the second substrate 201, and may thus be included in the stack structures GS1, GS2, GS3 and GS4. The horizontal electrodes 185 may be disposed between the second substrate 201 and upper interconnection structures 170 and 175. The number of horizontal electrodes 185 in contact with the memory cells CJ may vary according to the storage capacity of the semiconductor device 100.

The horizontal electrodes 185 may form second signal lines (S21, S22, . . . , S2n) electrically connected to the second conductive layer 150 illustrated in FIG. 1, and may be included in word lines. Accordingly, the second horizontal electrodes 185 may be referred to as some of the word lines, but the present disclosure is not limited thereto.

The interlayer insulating layers 120 alternately and repeatedly stacked with the spaced apart horizontal electrodes 185 may be disposed. The interlayer insulating layers 120 may extend with interlayer insulating layers 120 of the adjacent molded structures MS1 and MS2. The interlayer insulating layers 120 may include an insulating material such as silicon oxide. An uppermost interlayer insulating layer 121, among the interlayer insulating layers 120, may be thicker than the remaining interlayer insulating layers 120.

The horizontal electrodes 185 may include a conductive material. For example, each of the horizontal electrodes 185 may be formed of polysilicon, W, Ru, Mo, Nb, Ni, Co, Ti, Ta, TiN, TaN, WN, NON, TiAl, TiAlN, TiSi, TiSiN, TaSi, TaSiN, RuTiN, NiSi, CoSi, or combinations thereof. For example, each of the horizontal electrodes 185 may include a single layer or multiple layers of the materials described above.

The molded structures MS1 and MS2 extending in the X-direction may be respectively disposed between two adjacent stack structures GS1, GS2, GS3 and GS4 in the Y-direction.

In an example, a first molded structure MS1 may be disposed between a first stack structure GS1 and a second stack structure GS2, and a second molded structure MS2 may be disposed between a third stack structure GS3 and a fourth stack structure GS4. In an example, the two stack structures GS2 and GS3, as well as one separation structure SS therebetween, may be disposed between two adjacent molded structures MS1 and MS2 in the Y-direction.

Each of the molded structures MS1 and MS2 may have a mold width W5 in the Y-direction and may extend by intersecting the cell region R1 and the extension region R2 in the X-direction, and the molded structures MS1 and MS2 may include sacrificial insulating layers 118 stacked and spaced apart from each other in the vertical direction (Z-direction). The mold width W5 may be equal to or greater than the electrode width W4, but the present disclosure is not limited thereto. The molded structures MS1 and MS2 may vertically overlap the second structure PERI, which may be a peripheral circuit structure. Lower ends of the molded structures MS1 and MS2 may be in contact with the etching stop layer 210, and upper ends thereof may be in contact with the cell region insulating layer 190.

The sacrificial insulating layers 118 may be vertically spaced apart from each other and stacked on the second substrate 201 and may be respectively disposed on the same level as the horizontal electrodes 185, and may be disposed between the second substrate 201 and the upper interconnection structures 170 and 175. In an example, the horizontal electrodes 185 of the first stack structure GS1 and the horizontal electrodes 185 of the second stack structure GS2 may be spaced apart from each other in the Y-direction with the sacrificial insulating layers 118 of the first molded structure MS1 interposed therebetween. In an example, the horizontal electrodes 185 of the third stack structure GS3 and the horizontal electrodes 185 of the fourth stack structure GS4 may be spaced apart from each other in the Y-direction with the sacrificial insulating layers 118 of the second molded structure MS2 interposed therebetween.

The interlayer insulating layers 120 alternately and repeatedly stacked with the sacrificial insulating layers 118 may be disposed. The interlayer insulating layers 120 may extend with interlayer insulating layers 120 of the adjacent stack structures GS1, GS2, GS3 and GS4. The interlayer insulating layers 120 may include an insulating material such as silicon oxide.

The sacrificial insulating layers 118 may include an insulating material, and may include an insulating material having etch selectivity with the interlayer insulating layer 120, and may include silicon nitride or silicon carbonitride, but the present disclosure is not limited thereto. The sacrificial insulating layers 118 may be disposed in a region remaining unaltered during a replacement process with the horizontal electrodes 185.

The separation structures SS may be disposed to extend in the Z-direction by penetrating through the horizontal electrodes 185. The separation structures SS may be connected to the second substrate 201 by penetrating through the entire horizontal electrodes 185 stacked on the second substrate 201. In FIG. 3, the separation structures SS are exemplified as having a side surface perpendicular to a bottom surface, but the present disclosure is not limited thereto, and the side surface of the separation structure SS may have a shape in which a width thereof decreases toward the second substrate 201 due to a high aspect ratio. Each of the separation structures SS may extend in the X-direction to separate the horizontal electrodes 185 from each other in the Y-direction, and may thus be divided into the first and second stack structures GS1 and GS2 or the third and fourth stack structures GS3 and GS4. According to example embodiments, a separation insulating layer 179 may be disposed on the separation structures SS, and a conductive layer may be further disposed in the separation insulating layer 179. The separation insulating layer 179 may include an insulating material such as silicon oxide or silicon nitride, and may include, for example, silicon oxide, silicon nitride, or silicon oxynitride.

The separation structures SS have a separation width W6 in the Y-direction, and the separation width W6 may be equal to or greater than the electrode width W4 and equal to or less than the mold width W5, but the present disclosure is not limited thereto.

Accordingly, as illustrated in FIG. 2, the stack structures GS1, GS2, GS3 and GS4, the molded structures MS1 and MS2 and the separation structures SS, which have a bar type extending in the X-direction, may extend the cell region R1 and the extension region R2 in succession. Based on the first molded structure MS1 and the second molded structure MS2 spaced apart from each other in the Y-direction, the stack structures GS1, GS2, GS3 and GS4 may be disposed on both sides of each molded structures MS1 and MS2, and the separation structures SS may be disposed on the other side of the stack structures GS1, GS2, GS3 and GS4. Specifically, the first stack structure GS1 and the second stack structure GS2 may be respectively disposed on both sides of the first molded structure MS1 in the Y-direction, and the third stack structure GS3 and the fourth stack structure GS4 may be respectively disposed on both sides of the second molded structure MS2 in the Y-direction. Accordingly, in each of the stack structures GS1, GS2, GS3 and GS4, the first or second molded structures MS1 and MS2 may be disposed on one side thereof in the Y-direction, and the separation structure SS may be disposed on the other side, and the stack structures GS1, GS2, GS3 and GS4 may be disposed on both sides of the separation structure SS in the Y-direction. The stack structures GS1, GS2, GS3 and GS4 and the molded structures MS1 and MS2 being disposed on one side in the Y-direction may be understood as the horizontal electrodes 185 of the stack structures GS1, GS2, GS3 and GS4 and the sacrificial insulating layers 118 of the molded structures MS1 and MS2 being disposed in succession in the Y-direction, and the interlayer insulating layers 120 disposed on the same level in the Z-direction may be disposed in succession between the adjacent stack structures GS1, GS2, GS3 and GS4 and the molded structures MS1 and MS2.

The stack structures GS1, GS2, GS3 and GS4, the molded structures MS1 and MS2 and the separation structures SS may maintain a uniform width across the cell region R1 and the extension region R2, but the present disclosure is not limited thereto.

The vertical structures VS may be disposed in boundary regions between the molded structures MS1 and MS2 and the stack structures GS1, GS2, GS3 and GS4, on the second substrate 201. Each of the vertical structures VS may be disposed to contact a selected one molded structure of the adjacent molded structures MS1 and MS2 and a selected one stack structure of the stack structures GS1, GS2, GS3 and GS4. Each of the vertical structures VS may form one memory cell string CJS. Referring to FIG. 2, the vertical structures VS of the first structure CELL may be spaced apart from each other in the X-direction and the Y-direction and may have a matrix arrangement. In some other examples, the vertical structures VS may be arranged in a zigzag shape in an X-Y plane. A separation distance I1 of the vertical structures VS in the X-direction may be different from a separation distance I2 in the Y-direction. For example, the separation distance I1 in the X-direction may be greater than the separation distance I2 in the Y-direction, but according to an example embodiment, the separation distances I1 and I2 may be equal to each other.

Each of the above vertical structures VS may include a first conductive layer 130 and an information storage structure 140 disposed in a hole simultaneously penetrating through the stack structures GS1, GS2, GS3 and GS4 and the molded structures MS1 and MS2, and protrusion portions 150 disposed between the first conductive layer 130 and the information storage structure 140, and the horizontal electrodes 185 or the sacrificial insulating layers 118.

The first conductive layer 130 may form a vertical pillar, and the information storage structure 140 may form a vertical pillar.

The first conductive layer 130 may be disposed in a center of a hole filled by the vertical structure VS and may have a pillar shape extending in the Z-direction. Alternatively, the first conductive layer 130 may have a U-shaped cross-section and may be filled with an insulating material inside. On the X-Y plane, the first conductive layer 130 may have a circular, elliptical or polygonal shape, and a radius d4 of the first conductive layer 130, that is, the longest distance d4 from the center (O) of the hole to an outer surface of the first conductive layer 130, may be equal to or less than a first thickness T1 of the first information storage layer 141, and may be equal to or less than the first thickness T1 of the first information storage layer 141, and may satisfy, for example, 10 nm or less.

The first conductive layer 130 may be spaced apart from the second substrate 201 and may be electrically insulated therefrom, and may be connected to one selected signal line of first signal lines (170a: S11, S12 . . . ) of the upper circuit interconnection line 170 by a corresponding stud 175, among the studs 175 on an upper surface. A level of an upper surface of the first conductive layer 130 may be the same as a level of an upper surface of the upper interlayer insulating layer 121, but the present disclosure is not limited thereto.

The first conductive layer 130 may include multiple layers, one or which is a barrier layer on a side surface and a lower surface, and the barrier layer may be a diffusion barrier. The first conductive layer 130 may include at least one selected from a semiconductor including impurities (e.g., doped silicon), a metal (e.g., tungsten, copper, aluminum, etc.), a conductive metal nitride (e.g., titanium nitride, tantalum nitride, etc.), a conductive oxide semiconductor (e.g., IGZO), a transition metal (e.g., titanium (Ti), tantalum (Ta), ruthenium (Ru), molybdenum (Mo), gold (Au), platinum (Pt), etc.), a multi-element conductive material (e.g., MoS₂, MoSe₂, WS, etc.). The barrier layer may include at least one of titanium (Ti), titanium nitride (TiN), tantalum (Ta), tantalum nitride (TaN), or tungsten nitride (WN). When the first conductive layer 130 includes a doped semiconductor, the first conductive layer 130 may be a semiconductor having a polycrystalline structure, such as polysilicon.

The information storage structure 140 may surround the first conductive layer 130. The information storage structure 140 may include an insulating material, and may have a U-shaped cross-section to cover a side surface and a lower surface of the first conductive layer 130 in the hole.

The information storage structure 140 may include a first information storage layer 141 and an interface insulating layer 143.

The first information storage layer 141 may be a ferroelectric layer. The first information storage layer 141 may have polarization characteristics depending on the electric field, and may have remanent polarization by dipoles even in the absence of an external electric field. The first information storage layer 141 may store data using a polarization state in the ferroelectric layer. Data may be recorded to the first information storage layer 141 by controlling a polarization state in the ferroelectric layer. Regions of the first information storage layer 141 facing the horizontal electrodes 185 that may be word lines may be regions for storing information using the polarization state.

The first information storage layer 141 may be a ferroelectric layer including a Hf-based compound, a Zr-based compound, and/or a Hf—Zr-based compound. For example, the Hf-based compound may be a HfO-based ferroelectric material, the Zr-based compound may include a ZrO-based ferroelectric material, and the Hf—Zr-based compound may include a hafnium zirconium oxide (HZO)-based ferroelectric material.

The first information storage layer 141 may include a ferroelectric material doped with impurities, for example, at least one of Zr, C, Si, Mg, Al, Y, N, Ge, Sn, Gd, La, Sc, or Sr. For example, the ferroelectric layer of the first information storage layer 141 may be a material obtained by doping at least one of impurities, Zr, C, Si, Mg, Al, Y, N, Ge, Sn, Gd, La, Sc and Sr in at least one of HfO₂, ZrO₂ or HZO. For example, the ferroelectric layer of the first information storage layer 141 may include Hf₁₋ₓZrₓO₂ (0≤x≤1), (Al, C, N, Gd, Y, Ta, La, Si)-doped HfO₂, or Al₁₋ₓScₓN (0≤x≤1).

The ferroelectric layer of the first information storage layer 141 is not limited to the types of materials described above, and may include a material having ferroelectric properties capable of storing information. For example, the ferroelectric layer of the first information storage layer 141 may include at least one of BaTiO₃, PbTiO₃, BiFeO₃, SrTiO₃, PbMgNdO₃, PbMgNbTiO₃, PbZrNbTiO₃, PbZrTiO₃, KNbO₃, LiNbO₃, GeTe, LiTaO₃, KNaNbO₃, BaSrTiO₃, HF_{0.5}Zr_{0.5}O₂, PbZrₓTi1−xO₃ (0<x<1), Ba(Sr, Ti)O₃, Bi₄ₓLaₓTi₃O₁₂ (0<x<1), SrBi₂Ta₂O₉, Pb₅Ge₅O₁₁, SrBi₂Nb₂O₉, or YMnO₃. The first information storage layer 141 may be a single layer or multiple layers of the above-described ferroelectric materials.

The first information storage layer 141 may have a first thickness T1. The first thickness T1 may be equal to or greater than the radius d4 of the first conductive layer 130, but the present disclosure is not limited thereto. The first thickness T1 may be about 10 nm or more.

The interface insulating layer 143 may be disposed on an inner surface of each hole of the vertical structure VS and may thus be formed to cover an outer surface of the first information storage layer 141, i.e., an outer side surface and a lower surface thereof. The interface insulating layer 143 may have a second thickness T2, and the second thickness T2 may be less than the first thickness T1. The second thickness T2 may be 1/10 to ⅕ of the first thickness T1, for example, 1 nm to 2 nm, but the present disclosure is not limited thereto.

As a ratio of the second thickness T2 to the first thickness T1 decreases and the radius d4 of the first conductive layer 130 decreases, an area ratio of an area of the interface insulating layer 143 to an area of the first information storage layer 141 may increase. In this case, the area is defined as a lateral area, and when the area is formed in a ring shape so as to have a concentric circle with respect to the center (O) of the first conductive layer 130, the area may be defined as an area of an interface of each layer. Accordingly, the area of the first information storage layer 141 may be defined as an area of a side surface of the first conductive layer 130, that is, an area of an inner surface of the first information storage layer 141, and the area of the interface insulating layer 143 may be defined as an area of an inner surface of the interface insulating layer 143, an interface between the first information storage layer 141 and the interface insulating layer 143. As the area of the interface insulating layer 143 increases and a thickness thereof decreases, the capacitance of the interface insulating layer 143 increases, and on the other hand, as the area of the first information storage layer 141 decreases and the thickness increases, the capacitance of the first information storage layer 141 decreases. When the capacitance of the first information storage layer 141 decreases, an electric field applied to the first information storage layer 141 increases, and accordingly, strong polarization may be induced and a memory window may increase. Additionally, when the capacitance of the interface insulating layer 143 increases, an electric field applied to the interface insulating layer 143 may decrease to improve the reliability thereof. The memory cell CJ may be implemented using a ferroelectric tunnel junction (FTJ) having a frame type, a ring type or a circular type forming concentricity in this manner, thereby simultaneously implementing securing a memory window and securing reliability according to a thickness change of the first conductive layer 130, the interface insulating layer 143 and the first information storage layer 141.

An interface insulating layer 164 may be an oxide, specifically, an oxide such as SiO, AIO, LiO, HfO, ZrO, TaO, WO or TiO, and may include at least one of an oxynitride such as SiON, AlON, or a high-K dielectric. The high-K dielectric may be a dielectric having a dielectric constant higher than that of silicon oxide.

The plurality of protrusion portions 150 surrounding the first conductive layer 130 and the information storage structure 140 may be spaced apart from each other in the Z-direction, and each of the protrusion portions 150 may be formed in a frame shape or an annular shape on different levels. Each of the protrusion portions 150 may include a second conductive layer 150, and each of the protrusion portions 150 in FIGS. 3 and 5 may be referred to as a second conductive layer 150. The second conductive layer 150 may include a semiconductor material including impurities, as a conductive material. For example, the second conductive layer 150 may include at least one of doped silicon, doped polysilicon, or an oxide semiconductor. The oxide semiconductor may be indium gallium zinc oxide (IGZO), but example embodiments are not limited thereto. For example, the oxide semiconductor may include at least one of Indium Tungsten Oxide (ITO), Indium Tin Gallium Oxide (ITGO), Indium Aluminium Zinc Oxide (IAZO), Indium Gallium Oxide (IGO), Indium Tin Zinc Oxide (ITZO), Zinc Tin Oxide (ZTO), Indium Zinc Oxide (IZO), Zinc Oxide (ZnO), Indium Gallium Silicon Oxide (IGSO), Indium Oxide (InO), Tin Oxide (SnO), Titanium Oxide (TiO), Zinc Oxynitride (ZnON), Magnesium Zinc Oxide (MgZnO), Indium Zinc Oxide (InZnO), Indium Gallium Zinc Oxide (InGaZnO), Zirconium Indium Zinc Oxide (ZrInZnO), Hafnium Indium Zinc Oxide (HfInZnO), Tin Indium Zinc Oxide (SnInZnO), Aluminum Tin Indium Zinc Oxide (AlSnInZnO), Silicon Indium Zinc Oxide (SiInZnO), Zinc Tin Oxide (ZnSnO), Aluminum Zinc Tin Oxide (AlZnSnO), Gallium Zinc Tin Oxide (GaZnSnO), Zirconium Zinc Tin Oxide (ZrZnSnO), or Indium Gallium Silicon Oxide (InGaSiO).

The second conductive layer 150 may include a metallic material. The second conductive layer 150 may include multiple layers, one or which is a barrier layer, similar to the first conductive layer 130, and the barrier layer may be a diffusion barrier. The second conductive layer 150 may include at least one selected from metals (e.g., tungsten, copper, aluminum, etc.), conductive metal nitrides (e.g., titanium nitride, tantalum nitride, etc.), transition metals (e.g., titanium (Ti), tantalum (Ta), ruthenium (Ru), molybdenum (Mo), gold (Au), platinum (Pt), etc.), and multi-element conductive materials (MoS₂, MoSe₂, WS, etc.). The barrier layer may include at least one of titanium (Ti), titanium nitride (TiN), tantalum (Ta), tantalum nitride (TaN), and tungsten nitride (WN).

The interface insulating layer 143 may be spaced apart from the horizontal electrodes 185 with the second conductive layer 150 interposed therebetween. Specifically, an inner surface of the second conductive layer 150 may be in contact with the interface insulating layer 143, and an outer surface thereof may be in contact with the horizontal electrodes 185 and/or the sacrificial insulating layers 118. For example, the second conductive layer 150 may have a frame shape or an annular shape in the X-Y plane. In an example, outer surfaces of each of the protrusion portions 150 may include a portion in contact with a sacrificial insulating layer 118 and a portion in contact with the horizontal electrode 185. In an example, the second conductive layers 150 of the vertical structures VS in contact with the first stack structure GS1 may be spaced apart from the second conductive layers 150 of the vertical structures VS in contact with the second stack structure GS2 in a next row by the sacrificial insulating layers 118 of the first molded structure MS1. The interlayer insulating layer 120 of the first molded structure MS1 may vertically overlap portions of each of the second conductive layers 150 of the vertical structures VS in contact with the first stack structure GS1, and may vertically overlap portions of each of the second conductive layers 150 of the vertical structures VS in contact with the second stack structure GS2. For example, the interlayer insulating layer 120 of the first molded structure MS1 and the stack structure GS1 adjacent thereto may protrude further toward the vertical structures VS than the sacrificial insulating layers 118 and the horizontal electrodes 185 disposed above and below in the Z-direction, and may contact the interface insulating layer 143 of the vertical structures VS between the protrusion portions 150 disposed above and below in the Z-direction.

Upper surfaces of each second conductive layer 150 may be disposed on the same level as upper surfaces of the horizontal electrodes 185 in contact therewith, and a lower surface of the second conductive layer 150 may be disposed on the same level as a lower surface of the horizontal electrodes 185 in contact therewith, but the present disclosure is not limited thereto.

That is, the protrusion portions 150 may be disposed to surround the first conductive layer 130 and the information storage structure 140 on each level of the first conductive layer 130 and the information storage structure 140 corresponding to the horizontal electrodes 185 and the sacrificial insulating layers 118. The protrusion portions 150 may be disposed to overlap the interlayer insulating layers 120 in an upper portion and a lower portion in the Z-direction, so that the adjacent protrusion portions 150 may be physically and electrically disconnected from each other.

An area of an outer surface of a portion in which the second conductive layer 150 is in contact with the horizontal electrodes 185 may be equal to or less than half of an outer surface of the second conductive layer 150, and the horizontal electrodes 185 may be disposed to overlap one row of vertical structures VS in the Y-direction by a length d2 less than an overall radius d1 of the vertical structure VS. For example, the horizontal electrodes 185 may be disposed to overlap one row of vertical structures VS in the Y-direction by the length d2 less than the overall radius d1 of the vertical structure VS and greater than half of the overall radius d1, but the present disclosure is not limited thereto. That is, when a length of the stack structure GS in the Y-direction is the electrode width W4, the electrode width W4 may include a length d2 overlapping the vertical structure VS and a length d3 not overlapping the vertical structure VS. An area of an outer surface of a portion in contact with the sacrificial insulating layers 118 may be greater than an area of an outer surface of a portion in contact with the horizontal electrodes 185 on the outer surface of the second conductive layer 150, but ¼ or more of the total area of the second conductive layer 150 may come into contact with the horizontal electrodes 185 so as to maintain electrical connection with the horizontal electrodes 185.

The vertical structure VS may be disposed in a circle or polygon in which the first conductive layer 130 has a predetermined radius d4 in the center (O) of the hole, on the X-Y plane, and the information storage structure 140 may surround a side surface of the first conductive layer 130, and the first information storage layer 141 may be disposed at a first thickness T1. An interface insulation layer 143 may surround the outer surface of the first information storage layer 141 at the second thickness T2 in the vertical structure VS, and a second conductive layer 150 may surround an outer surface of the interface insulation layer 143 in the vertical structure VS. Accordingly, with respect to the center (O) of the first conductive layer 130, each of the layers 141, 143 and 150 surrounding the first conductive layer 130 may be formed in a ring type having a concentricity (O). Accordingly, diameters of each of the layers 141, 143 and 150 may be determined according to a stacking order and a stacking thickness. A diameter of the information storage structure 140 may be the same as a first width W1, the diameter of the interface insulating layer 143, the diameter of the second conductive layer 150 on an outer side thereof may satisfy a second width W2, greater than the first width W1, and a diameter of the first information storage layer 141 on an inner side thereof may satisfy a third width W3, less than the first width W1. When the first conductive layer 130 has a square or polygonal shape, each of the layers 141, 143 and 150 may have a frame shape, and a relationship between maximum diameters of each frame may be similar to that described above.

In this case, in the ring type of the concentricity (O), due to the radius d4 of the first conductive layer 130 and the first thickness T1 of the first information storage layer 141, an area of an inner surface of the first information storage layer 141 may be different from an area of an outer surface thereof.

That is, the area of the inner surface of the first information storage layer 141 in contact with the first conductive layer 130 is less than the area of the outer surface thereof in contact with the interface insulating layer 143, and a difference in the area of the inner surface and the outer surface thereof increases as a thickness thereof increases. Accordingly, the area of the first information storage layer 141 may have a smaller value with respect to the area of the interface insulating layer 143. Accordingly, the capacitance of the first information storage layer 141 may be set to be smaller to increase a magnitude of an applied electric field, and accordingly, polarization thereof may be formed more clearly.

In the vertical structure VS, ferroelectric tunnel junction elements included in the memory cells CJ may be disposed in regions corresponding to each horizontal electrode 185 to form a single memory cell string CJS, and in one memory cell string CJS, the first conductive layers 130 may be connected to each other to form a vertical pillar, and the second conductive layers 150 may be physically and electrically separated from each other so that different voltages may be received by or applied to each horizontal electrode 185.

The first conductive layer 130 and the second conductive layer 150 may include the same metallic material, and may also include the same semiconductor material. Alternatively, when the first conductive layer 130 includes the metallic material, the second conductive layer 150 may include the semiconductor material. The selection of materials for the first conductive layer 130 and the second conductive layer 150 may be implemented in various manners in the range of materials having conductivity, and may be implemented in various ways as long as the structure in which the first information storage layer 141 is disposed toward the first conductive layer 130 and the interface insulating layer 143 is disposed toward the second conductive layer 150.

The vertical structures VS may penetrate through the horizontal electrodes 185, may extend in the vertical direction (Z-direction), perpendicular to the upper surface of the second substrate 201, and may have a pillar shape with an inclined side surface in which a width thereof becomes narrower as the vertical structure VS approaches the second substrate 201 depending on the aspect ratio. The second width W2 of the upper surfaces of the vertical structures VS may be less than the width of the lower surfaces of the vertical structures VS.

In the extension region R2, each of the stack structures GS1, GS2, GS3 and GS4 may have a stepwise structure in which the horizontal electrodes 185 expose pad regions GP so that the horizontal electrodes 185 and the contact plugs CS on different levels may be physically and electrically connected to each other. When there is a stepwise structure in which the horizontal electrodes 185 expose the pad regions GP in the extension region R2, the molded structures MS1 and MS2 adjacent thereof may also have the same stepwise structure.

The contact plugs CS may extend in the Z-direction and may have an inclined side surface so that a width thereof becomes narrower as contact plug CS approaches the second substrate 201. The contact plugs CS may electrically connect the horizontal electrodes 185 to the lower interconnection structure 12 in the first structure PERI. The contact plugs CS may be physically and electrically connected to the horizontal electrodes 185 in each pad region GP, thus applying an electrical signal to the horizontal electrodes 185. The contact plugs CS may be in contact with the pad regions GP of the horizontal electrodes 185 while being partially sunken in the pad regions GP thereof, but the present disclosure is not limited thereto. To this end, pad regions 130P of the horizontal electrodes 185 may be formed to be thicker than other portion, but the present disclosure is not limited thereto. According to an example embodiment, the contact plugs CS may be disposed to extend into the second substrate 201 by penetrating through a region in which the horizontal electrodes 185 form a stepwise structure, but the present disclosure is not limited thereto.

The contact plugs CS may include a metallic material, and may include, for example, tungsten (W), aluminum (Al), copper (Cu), tungsten nitride (WN), tantalum nitride (TaN), titanium nitride (TiN), or combinations thereof.

The second structure CELL may further include a cell region insulating layer 190 on the upper interlayer insulating layer 121. The cell region insulating layer 190 may include an insulating material, and may include, for example, silicon oxide, silicon nitride, silicon carbide, or silicon oxynitride.

The second structure CELL may further include studs 175 penetrating through the cell region insulating layer 190 and electrically connected to the first conductive layer 130 of the vertical structure VS, and upper circuit interconnection lines 170 electrically connected to the studs 175 on the cell region insulating layer 190. The upper circuit interconnection lines 170 may include, for example, bit lines BL as first signal lines 170a (S11, S12, . . . ), and may include word lines WL as second signal lines 170b (S21, S22, . . . ) in the extension region R2.

The studs 175 may penetrate through the cell region insulating layer 190 and may have a width that decreases as the stud 175 approaches the first conductive layer 130, and may be configured so that a lower surface thereof may be in contact with the upper surface of the first conductive layer 130 and a width of the lower surface thereof may be less than the upper surface of the first conductive layer 130.

The upper interconnection structures 170 and 175 may electrically connect the vertical structures VS to the circuit elements 12. The upper interconnection structures 170 and 175 may include a conductive material, and may include, for example, tungsten (W), copper (Cu), and aluminum (Al), and each of the components may further include a diffusion barrier layer including at least one of titanium (Ti), titanium nitride (TiN), tantalum (Ta), tantalum nitride (TaN), or tungsten nitride (WN). According to example embodiments, the number of layers and the arrangement form of the upper interconnection structures 170 and 175 may be variously changed.

As illustrated in FIGS. 2 to 5, the vertical structure VS may have a symmetrical shape with the center (O) of the hole as an axis, and the first conductive layer 130 has a pillar shape based on a line connecting the center (O) in a vertically cut cross-section, and each layer surrounding the first conductive layer 130, specifically, the first information storage layer 141 and the interface insulating layer 143, may be formed in a U shape with symmetry with the center (O) as the axis. In this specification, the first information storage layer 141 may be referred to as a ferroelectric layer 141.

Because the unit memory cell CJ includes a ring-type information storage structure 140 between the first conductive layer 130 and the second conductive layer 150, areas of each layer may be determined according to a thickness and an arrangement order of each layer. Accordingly, the capacitance of the ferroelectric layer 141, which approaches the center (O) and is thick, may be further reduced, and the capacitance of the interfacial insulating layer 143 surrounding the ferroelectric layer with a thin thickness and disposed further from the center (O) than the ferroelectric layer 141 may be further increased. In this manner, the desired capacitance may be satisfied according to the thickness and arrangement order of each layer, thereby improving the storage function of the memory cell CJ.

The first conductive layer 130 and the information storage structure 140 may extend between a plurality of unit memory cells CJ of the memory cell string CJS forming a line, so that the first conductive layer 130 and the information storage structure 140 may be connected to each other. However, due to a voltage applied to the second conductive layer 150, the polarization of the ferroelectric layer of the information storage structure 140 of the corresponding cell may be formed differently for each unit memory cell CJ, so that allocated information may be stored in each unit memory cell CJ.

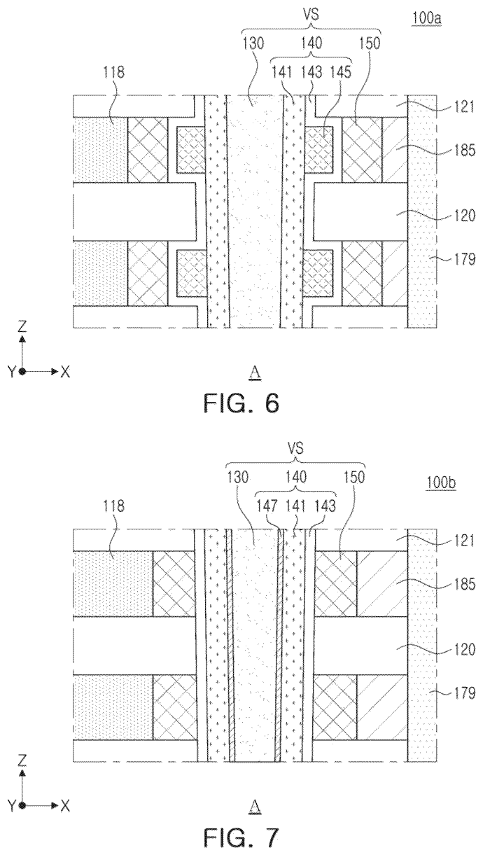

Hereinafter, various modified examples of the components of the above-described example embodiment will be described with reference to FIGS. 6 to 9, respectively. The various modified examples of the components of the above-described embodiment described below will be described with a focus on modified components or replaced components. Here, the components described above may be directly cited without a separate detailed description, or the description may be omitted. Additionally, the modified or replaceable components described below may improve at least one of the contact region, reliability, performance or productivity of the semiconductor device. Additionally, the modified or replaceable components described below are described with reference to the drawings below, but the modified or replaceable components may be combined with each other or with the components described above to form a semiconductor device according to an example embodiment.

FIGS. 6 to 9 are partially enlarged views of portion ‘A’ of FIG. 3.

Referring to FIG. 6, in an exemplary semiconductor device 100a, the above-described protrusion portions may be replaced with protrusion portions including a third conductive layer 145, the interface insulating layer 143, and the second conductive layer 150.

The third conductive layer 145 may be included in the protrusion portions and may be disposed between the first information storage layer 141 and the interface insulating layer 143. The third conductive layer 145 may be disposed in a ring type on an outer surface of the first information storage layer 141 including in a vertical pillar, and may be disposed so that an inner surface thereof is in contact with the first information storage layer 141 and an outer surface thereof is in contact with the interface insulating layer 143. Additionally, the interface insulating layer 143 may be bent so that an upper surface and a lower surface of the third conductive layer 145 are surrounded by the interface insulating layer 143, and may extend downwardly while surrounding the third conductive layer 145. The third conductive layer 145 may include a conductive material, and may include a semiconductor material including impurities, as the conductive material. For example, the third conductive layer 145 may include at least one of doped silicon, doped polysilicon, or an oxide semiconductor. The oxide semiconductor may be IGZO (indium gallium zinc oxide), but an example embodiment is not limited thereto. For example, the oxide semiconductor may include Indium Tungsten Oxide (ITO), Indium Tin Gallium Oxide (ITGO), Indium Aluminum Zinc Oxide (IAZO), Indium Gallium Oxide (IGO), Indium Tin Zinc Oxide (ITZO), Zinc Tin Oxide (ZTO), indium Zinc Oxide (IZO), Zinc Oxide (ZnO), Indium Gallium Silicon Oxide (IGSO), Indium Oxide (InO), Tin Oxide (SnO), Titanium Oxide (TiO), Zinc Oxynitride (ZnON), Magnesium Zinc Oxide (MgZnO), Indium Zinc Oxide (InZnO), Indium Gallium Zinc Oxide (InGaZnO), Zirconium Indium Zinc Oxide (ZrInZnO), Hafnium Indium Zinc Oxide (HfInZnO), Tin Indium Zinc Oxide (SnInZnO), Aluminum Tin Indium Zinc Oxide (AlSnInZnO), Silicon Indium Zinc Oxide (SiInZnO), Zinc Tin Oxide (ZnSnO), Aluminum Zinc Tin Oxide (AlZnSnO), Gallium Zinc Tin Oxide (GaZnSnO), Zirconium Zinc Tin Oxide (ZrZnSnO), or Indium Gallium Silicon Oxide (InGaSiO).

The third conductive layer 145 may include a metallic material. Specifically, the third conductive layer 145 may include at least one selected from metals (e.g., tungsten, copper, aluminum, etc.), conductive metal nitrides (e.g., titanium nitride, tantalum nitride, etc.), transition metals (e.g., titanium (Ti), tantalum (Ta), ruthenium (Ru), molybdenum (Mo), gold (Au), platinum (Pt), etc.), multi-element conductive materials (MoS₂, MoSe₂, WS, etc.).

The third conductive layer 145 may include the same material as the first conductive layer 130 or the second conductive layer 150, and may function as a floating gate.

Referring to FIG. 7, in an exemplary semiconductor device 100b, the information storage structure 140 of the vertical structure VS described above may further include a first insulating layer 147. The first insulating layer 147 may be disposed between the first conductive layer 130 and the first information storage layer 141 and may include the same material as the interface insulating layer 143, but the present disclosure is not limited thereto. The first insulating layer 147 may also have a thickness less than the first thickness T1 of the first information storage layer 141, and may be formed in a U shape by surrounding the side surface and the lower surface of the first conductive layer 130.

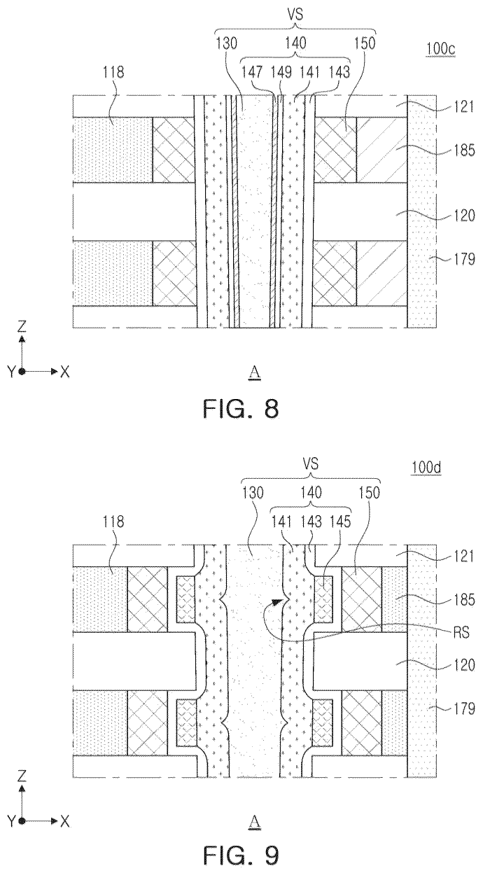

Referring to FIG. 8, in an exemplary semiconductor device 100c, the information storage structure 140 of the semiconductor device 100b of FIG. 7 may further include a second information storage layer 149. The second information storage layer 149 may be disposed between the first insulating layer 147 and the first information storage layer 141, and may have a thickness less than the first thickness T1 of the first information storage layer 141, and may be formed in a U shape by surrounding a side surface and a lower surface of the first insulating layer 147.

The second information storage layer 149 may be a charge trapping layer capable of storing data using a charge trap. The second information storage layer 149 may include at least one of SiO, SiN, SiON, SiO/SiN, SiO/SiON, SiO/AlO, SiO/HfO, SiO/SiN/SiO, or SiO/nano-crystal. Here, expressions such as SiO/SiN may refer to a stack structure of a material layer of SiN and a material layer of SiO. The second information storage layer 149 may include at least one of Si(O)N, or (Hf, Zr, Al, C, N, Gd, Y, Ti, La, Ta)-doped Si(O)N. When the information storage structure 140 of the semiconductor device 100c further includes the second information storage layer 149 together with the first information storage layer 141, the memory window may be further increased.

Referring to FIG. 9, a first information storage layer 141 included in the information storage structure 140 of a semiconductor device 100d may be expanded in width in a portion in contact with the protrusion portion. Specifically, when the protrusion portion includes an annular third conductive layer 145, an outer surface portion of the first information storage layer 141 in contact with the third conductive layer 145 may protrude outwardly toward the third conductive layer 145. Accordingly, a protruding region in which an outer surface portion in contact with the third conductive layer 145 protrudes further outwardly than an outer surface portion in contact with the interface insulating layer 143 may be included. Accordingly, an outer surface of the first information storage layer 141 may have repetitive protruding regions in a portion overlapping the horizontal electrodes 185 or the sacrificial insulating layers 118.

Accordingly, the inner surface of the first information storage layer 141 may also include a recessed region RS in a region corresponding to the protruding region. A shape of the recessed region RS of the inner surface of the first information storage layer 141 may not accurately match a protruding region of an outer surface thereof, and the recessed region RS of the inner surface may be formed to have a concave tip, but is not limited thereto. Despite a discontinuous shape of the inner surface and the outer surface, the first information storage layer 141 may satisfy a predetermined thickness T1 or more. In addition to those illustrated in FIGS. 5 to 9, the semiconductor device 100d may further include additional insulating layers.

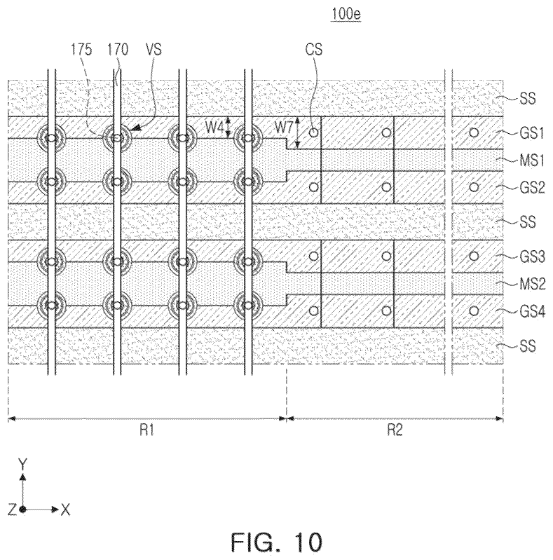

Hereinafter, various modified examples will be described with reference to FIGS. 10 to 20. FIGS. 10 to 20 illustrate modified examples of a top view of the semiconductor device 100 of FIG. 2, which may be understood as modified examples in which a length, i.e., a width of a stack structure GS and a molded structure MS in the Y-direction is variously modified. FIGS. 10 to 20 further illustrate upper circuit interconnection lines 170 applicable to the top view of FIG. 2 in order to exhibit a connection relationship between the upper circuit interconnection lines 170, which are first signal lines (S11, S12, . . . ) in respective semiconductor devices 100e to 1000, and horizontal insulating layers 185 of the stack structures GS, which are second signal lines (S21, S22, . . . , S2n). Hereinafter, the upper circuit interconnection lines 170 may be described as bit lines (BL, 170), but the present disclosure is not limited thereto.

Referring to FIG. 10, in the semiconductor device 100e, bit lines 170 simultaneously connected to the first conductive layers 130 of vertical structures VS forming each column, among the vertical structures VS forming a matrix, are disposed. Accordingly, each bit line 170 may simultaneously contact a column of vertical structures VS through each stud 175 to apply a signal or read a current.

The stack structures GS1, GS2, GS3 and GS4 of the semiconductor device 100e may be formed in a line type in the X-direction, but may have a first width W4 in the Y-direction in the cell region R1, and may have a second width W7 in the Y-direction in the extension region R2. The second width W7 of the extension region R2 may be greater than the first width W4 of the cell region R1, and the second widths W7 of the stack structures GS1, GS2, GS3 and GS4 on both sides of a molded structure MS1 or MS2 may have a form that expands toward the molded structures MS1 and MS2. Accordingly, a width of the molded structures MS1 and MS2 of the cell region R1 may be less than a width of the molded structures MS1 and MS2 of the extension region R2.

In this manner, side surfaces of the stack structure GS1, GS2, GS3 and GS4 in contact with the separation structure SS may extend straight in the X-direction without bends, but side surfaces of the stack structure GS1, GS2, GS3 and GS4 in contact with the molded structures MS1 and MS2 may have bends in which a width expands from the first width W4 to the second width W7, thereby implementing stack structure GS1, GS2, GS3 and GS4 having a greater width in the extension region R2.

The stack structure GS1, GS2, GS3 and GS4 having a greater width in the extension region R2 may secure a greater area of the pad regions GP respectively contacting the contact plugs CS, thereby preventing misalignment.

In addition, because the stack structures GS1, GS2, GS3 and GS4 have a greater width in the extension region R2, when the stack structures GS1, GS2, GS3 and GS4 form steps in the extension region R2, the stack structures GS1, GS2, GS3 and GS4 may be formed not only to have step portions in the X-direction, but also to have step portions in the Y-direction, so that various types of step shapes may be implemented.

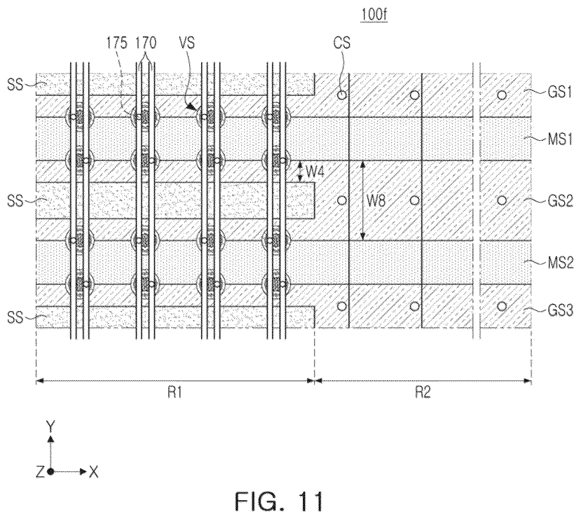

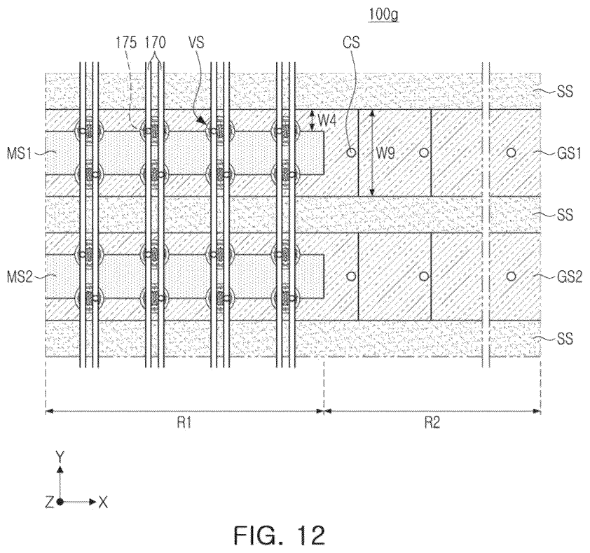

Referring to FIG. 11, in a semiconductor device 100f, the separation structure SS may be disposed only in the cell region R1, and the separation structure SS may not be disposed in the extension region R2. Accordingly, the two stack structures GS2 facing each other with the separation structure SS interposed therebetween may be integrated in the extension region R2 to contact the horizontal electrodes 185 of each layer by one contact plug CS. That is, the horizontal electrodes 185 in contact with the one contact plug CS may form a single plate having a third width W8 in the extension region R2, and may be separated into two regions having a first width W1 by the separation structure SS in the cell region R1 and may thus contact each of the vertical structures VS in each row.

Accordingly, two rows of vertical structures VS may simultaneously receive electrical signals conducted by the one contact plug CS, but bit lines 170 passing through the two rows of vertical structures VS may be allocated two per column, and may be physically and electrically connected by the studs 175 to alternating rows, thus forming one-to-one correspondence.

Referring to FIG. 12, in a semiconductor device 100g, molded structures MS1 and MS2 may be disposed only in the cell region R1, and the molded structures MS1 and MS2 may not be disposed in the extension region R2. Accordingly, two stack structures GS1 facing each other with the molded structures MS1 and MS2 interposed therebetween may be integrated in the extension region R2 to contact the horizontal electrodes 185 of each layer by the one contact plug CS. That is, the horizontal electrodes 185 in contact with the one contact plug CS may form a plate having a fourth width W9 in the extension region R2, and may be separated into two regions having a first width W4 by the molded structures MS1 and MS2 in the cell region R1 and may thus contact the vertical structures VS of each row, respectively.

Accordingly, two rows of vertical structures VS may simultaneously receive electrical signals by the one contact plug CS, but bit lines 170 passing through the two rows of vertical structures VS may be allocated two per column, and may be physically and electrically connected by the studs 175 to alternating rows, thus forming one-to-one correspondence. In this case, the separation structure SS has the same width and may continuously extend in the X-direction from the cell region R1 to the extension region R2, but the present disclosure is not limited thereto.

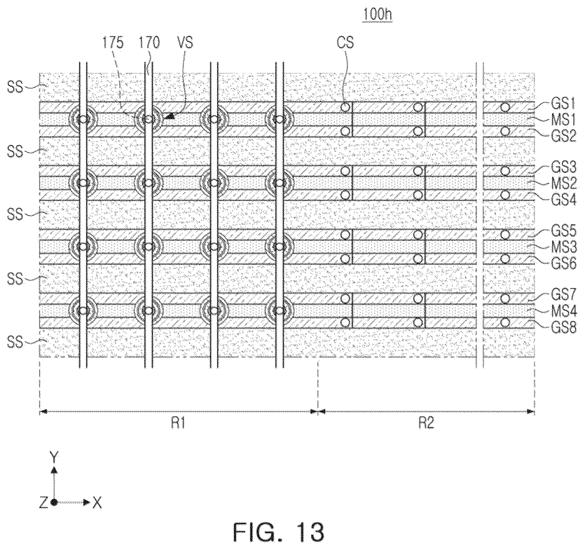

Referring to FIG. 13, in a semiconductor device 100h, two of stack structures GS1 to GS8 may be disposed on both sides of one row of vertical structures VS. That is, for the stack structures GS1 to GS8 disposed on one side of the vertical structure VS, the stack structures GS1 to GS8 in contact with each second conductive layer 150 from the other side thereof may be further disposed in the semiconductor device 100 of FIG. 2.

The separation structure SS and the stack structures GS1 to GS8 on both sides of the separation structure SS may be further disposed in a region having the molded structures MS1 to MS4 formed therein, so that two stack structures GS1 to GS8 separated from each other with respect to a single vertical structure VS may come into contact with both sides thereof. Each of the stack structures GS1 to GS8 may receive electrical signals by each contact plug CS, and thus, even when the horizontal electrodes 185 of the stack structure GS1 to GS8 and the second conductive layer 150 of the vertical structure VS are poorly contacted and the electronic signals are not applied, the horizontal electrodes 185 of the other side and the second conductive layer 150 may be in contact with each other, thereby minimizing defects thereof. In this case, the bit line 170 may be allocated to each of the vertical structures VS of each row, but the present disclosure is not limited thereto.

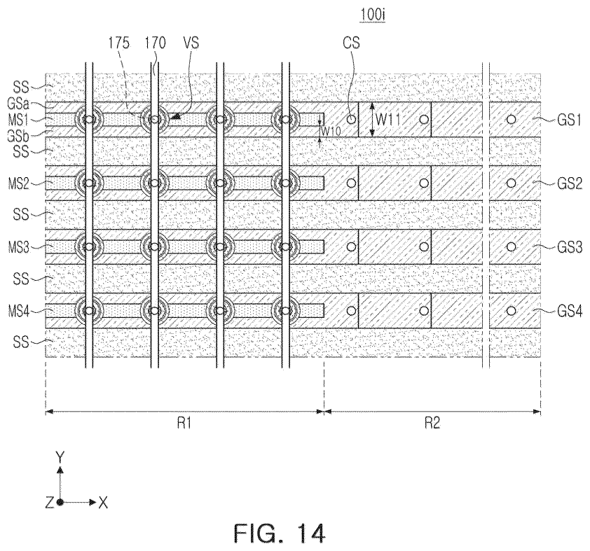

Referring to FIG. 14, in a semiconductor device 100i, two of stack structures GSa to GSb disposed on both sides of one row of vertical structures VS in the semiconductor device 100h of FIG. 13 may be integrated in the extension region R2 and may thus be included in a single stack structure (GS1 to GS4). In the cell region R1, two stack structures GSa to GSb on both sides of the vertical structure VS, each of which has a fifth width W10, may be disposed, and the two stack structures GSa to GSb may be connected to each other in the extension region R2 to form the single stack structure GS1 to GS4 having a sixth width W11 greater than the fifth width W10, thereby receiving the signal by the one contact plug CS.

Accordingly, the number of contact plugs CS may be reduced, and in this case, the bit line 170 may be allocated to each vertical structure VS of the column, one by one, but the present disclosure is not limited thereto.

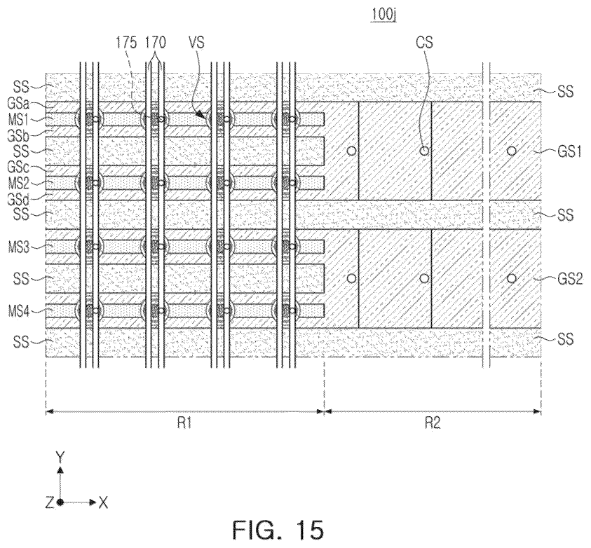

Referring to FIG. 15, in a semiconductor device 100j, the two stack structures GSa to GSb disposed on both sides of the vertical structures VS in one row and two stack structures GSc to GSd disposed on both sides of the vertical structures VS in a row adjacent thereof in the semiconductor device 100i of FIG. 14 may be integrated in the extension region R2 and may thus be included in one stack structure GS1 or GS2. In the cell region R1, the two stack structures GSa to GSb spaced apart from each other may be disposed on both sides of the vertical structure VS, and in the extension region R2, four stack structures GSa to GSd may be connected to each other and may thus be included in one stack structure GS1 or GS2, so that signals may be applied to two rows of vertical structures VS by the one contact plug CS.

Accordingly, the number of contact plugs CS may be reduced, and in this case, the bit lines 170 passing through two rows of vertical structures VS may be allocated two per column, and may be physically and electrically connected to alternating rows, thus forming one-to-one correspondence.

In FIG. 15, in the cell region R1, molded structures MS1 to MS4 may be disposed between the two stack structures GSa to GSb in contact with one vertical structure VS, and a separation structure SS may be disposed between the two stack structures GSa to GSb respectively coming into contact with different vertical structures VS.

In FIG. 15, a side surface of the integrated stack structures GS1 and GS2 in the extension region R2 is illustrated as extending straight without bent portions, but the present disclosure is not limited thereto, and a width of the integrated stack structures GS1 and GS2 in the Y-direction in the extension region R2 may have a bent portion so that the width may be reduced to some extent.

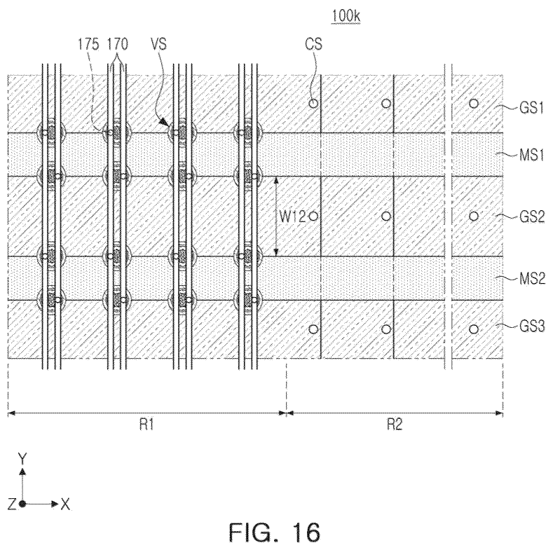

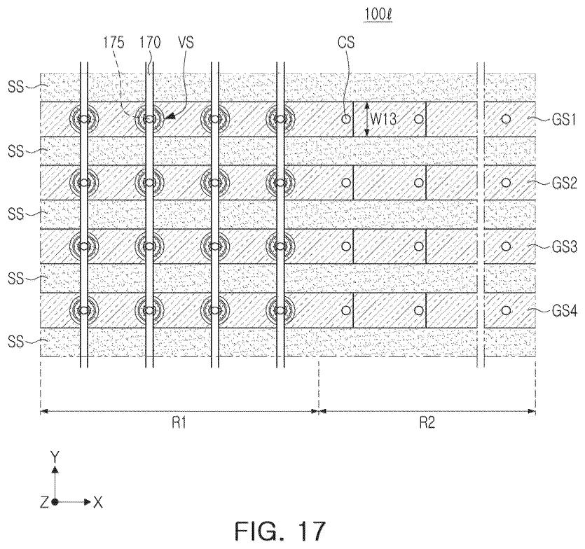

Referring to FIG. 16, in a semiconductor device 100k, molded structures MS1 and MS2 and stack structures GS1, GS2 and GS3 may be alternately disposed without the separation structure SS. That is, the stack structures GS1, GS2 and GS3 extending in the X-direction may be arranged alternately with the molded structures MS1 and MS2 in the Y-direction so as to simultaneously contact the vertical structures VS of two adjacent rows.

Accordingly, the vertical structures VS of two adjacent rows may simultaneously be in contact with one horizontal electrode 185, and signals may be applied to two rows of vertical structures VS by one contact plug CS.

Accordingly, two rows of vertical structures VS may simultaneously receive electrical signals by one row of contact plugs CS, but the bit lines 170 passing through the two rows of vertical structures VS may be allocated two per column, and may be physically and electrically connected by the studs 175 to alternating rows, thus forming one-to-one correspondence. In this case, the molded structures MS1 and MS2 may have the same width and may extend continuously in the X-direction from the cell region R1 to the extension region R2, and the stack structures GS1, GS2 and GS3 may also have the same seventh width W12 and may extend continuously in the X-direction from the cell region R1 to the extension region R2, but the present disclosure is not limited thereto.

Referring to FIG. 17, a semiconductor device 100l may be disposed so that the stack structures GS1, GS2, GS3 and GS4 and the separation structures SS are alternately arranged in the Y-direction without the molded structure.

Specifically, the vertical structures VS of each row may penetrate respective stack structures GS1, GS2, GS3 and GS4, and the horizontal electrodes 185 of the stack structures GS1, GS2, GS3 and GS4 may be in contact with an entire outer surface of the second conductive layer 150 of the vertical structures VS on each level.

Accordingly, reliability of the electrical connection between the vertical structures VS of each row and the horizontal electrodes 185 of the stack structures GS1, GS2, GS3 and GS4 may be secured. The respective stack structures GS1, GS2, GS3 and GS4 may be disposed for each of the vertical structures VS of each row, and each of the stack structures GS1, GS2, GS3 and GS4 may have a width W13 greater than a width of the stack structure GS of FIG. 2 in the Y-direction so that the vertical structures VS may be completely penetrated. In this case, the width W13 in the Y-direction may be disposed to have a larger width in the extension region R2, but the present disclosure is not limited thereto. The bit line 170 may be allocated one by one to the vertical structures VS of each column.

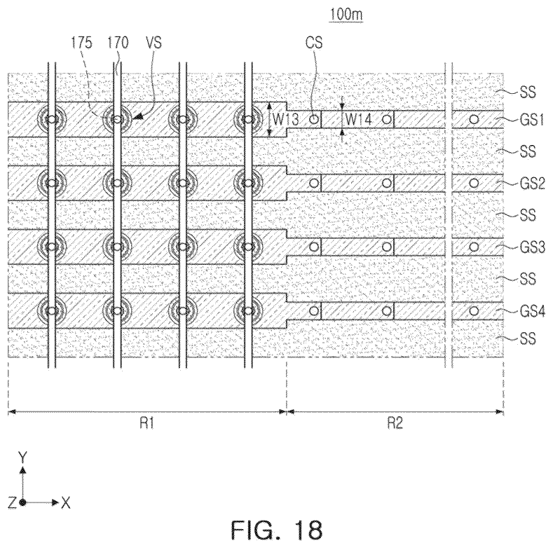

Referring to FIG. 18, a semiconductor device 100m may be configured so that each of the stack structures GS1, GS2, GS3 and GS4 may have a width W13 in the Y-direction in the cell region R1, but may have a width W14 in the extension region R2, which is smaller than the width W13, in the semiconductor device 100l of FIG. 17. That is, a distance between each pad region GP in the extension region R2 may be sufficiently secured, thereby minimizing short circuits with each adjacent stack structure GS1, GS2, GS3 and GS4. In this case, the bit line 170 may be allocated one by one to each vertical structure VS of each column, but the present disclosure is not limited thereto.

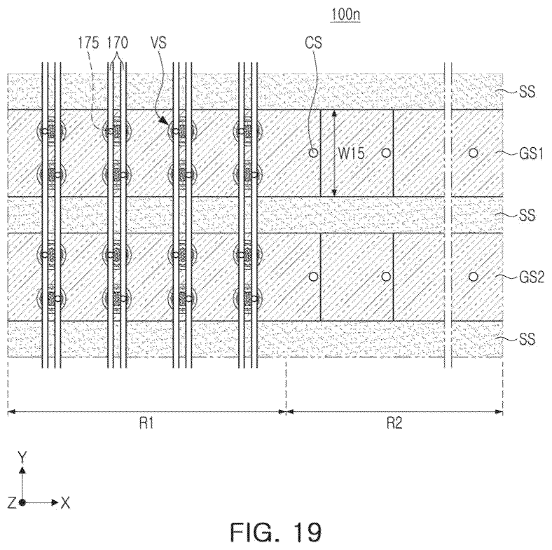

Referring to FIG. 19, in a semiconductor device 100n, the width W15 of the stack structures GS1 and GS2 in the Y-direction may be expanded so that two rows of vertical structures VS are simultaneously penetrated, in the semiconductor device 100m of FIG. 17.

Because the two rows of vertical structures VS are simultaneously in contact with the stack structures GS1 and GS2, the number of contact plugs CS may be reduced, and the bit lines 170 passing through the two rows of vertical structures VS are allocated two per each column, and may be physically and electrically connected to alternating rows, thus forming one-to-one correspondence.

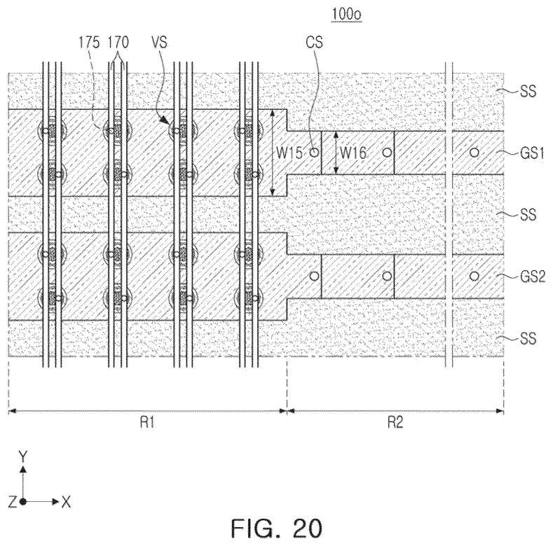

Referring to FIG. 20, a semiconductor device 1000 may be configured so that each of the stack structures GS1 and GS2 may have a width W15 in the Y-direction in the cell region R1, but may have a width W16 in the extension region R2, which is smaller than the width W15, in the semiconductor device 100n of FIG. 19. That is, a distance between each pad region GP in the extension region R2 may be sufficiently secured, thereby minimizing the risk of short circuits with the neighboring stack structures GS1 and GS2. In this case, the bit lines 170 passing through the two rows of vertical structures VS may be allocated two per each column, and may be physically and electrically connected to alternating rows, thus forming one-to-one correspondence. An electrical connection and configuration of the stack structures GS1 and GS2, the contact plug CS, and the bit lines 170 may be modified in various manner.

In FIGS. 10 to 20, the upper circuit interconnection lines 170 electrically connected to the first conductive layer 130 of the vertical structures VS are described as bit lines (BL, 170), and the horizontal electrodes 185 connected to the second conductive layer 150 are described as functioning as word lines, but the present disclosure is not limited thereto, and the upper circuit interconnection lines 170 electrically connected to the first conductive layer 130 may function as word lines, and the horizontal electrodes 185 connected to the second conductive layer 150 may function as bit lines.

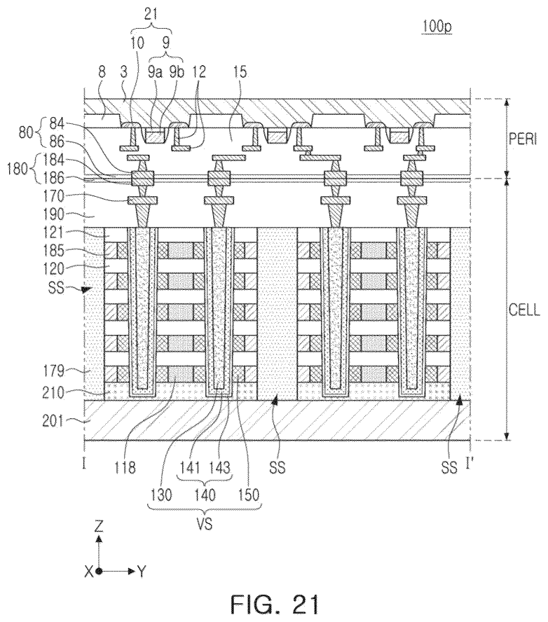

Hereinafter, with reference to FIG. 21, another bonding structure of a semiconductor device 100p will be described.

Referring to FIG. 21, a semiconductor device 100p may include a first structure PERI including a substrate 3 and a second structure CELL including a second substrate 201. The second structure CELL may be disposed below the first structure PERI.

In example embodiments, on the contrary, the second structure CELL may be disposed above the first structure PERI.

The description of the first structure PERI described above with reference to FIGS. 2 to 20 may be applied to the first structure PERI. However, a lower bonding structure 80 may be applied to the first structure PERI.

The lower bonding structure 80 may be connected to the lower interconnection structure 12. The lower bonding structure 80 may include a lower bonding via, a lower bonding pad 84, and a lower bonding insulating layer 86. The lower bonding via may be connected to the lower interconnection structure 12. The lower bonding pad 84 may be connected to the lower bonding via. The lower bonding via and the lower bonding pad 84 may include a conductive material, and may include, for example, tungsten (W), copper (Cu), and aluminum (Al), and each of the components may further include a diffusion barrier. The lower bonding insulating layer 86 may also function as a diffusion barrier layer of the lower bonding pad 84, and may include at least one of SiCN, SiO, SiN, SiOC, SiON, or SiOCN. The lower bonding insulating layer 86 may have a thickness thinner than a thickness of the lower bonding pad 84, but is not limited thereto.

The lower capping layer 15 may be a portion in each operation of forming the lower interconnection structure 12 and the lower bonding structure 80.

The second structure CELL, the vertical structure VS above the second substrate 201, the contact plugs CS for electrical connection with the peripheral circuit region PERI, the stack structure GS, the upper interconnection structures 170 and 175 above the molded structure MS, and an upper bonding structure 180 connected to the upper interconnection structures 170 and 175 may be included.

The upper bonding structure 180 may be connected to the upper interconnection line 170 and 175. For example, the upper circuit interconnection line 170 may be electrically connected to the upper bonding structure 180. The upper bonding structure 180 may include an upper bonding via, an upper bonding pad 184, and an upper bonding insulating layer 186. The upper bonding via may be connected to the upper circuit interconnection line 170. The upper bonding pad 184 may be connected to the upper bonding via. The upper bonding via and the upper bonding pad 184 may include a conductive material, may include, for example, tungsten (W), copper (Cu), and aluminum (Al), and each of the components may further include a diffusion barrier. The upper bonding insulating layer 186 may also function as a diffusion barrier layer of the upper bonding pad 184, and may include at least one of SiCN, SiO, SiN, SiOC, SiON, or SiOCN. The upper bonding insulating layer 186 may have a thickness thinner than a thickness of the upper bonding pad 184, but is not limited thereto.

The lower bonding structure 80 and the upper bonding structure 180 may be directly contacted and bonded or connected by hybrid bonding. For example, the lower bonding pad 84 may be in contact with and may be bonded to the upper bonding pad 184 by copper-to-copper bonding, and the lower bonding insulating layer 86 may be in contact with and may be bonded to the upper bonding insulating layer 186 by dielectric-to-dielectric bonding. The lower bonding structure 80 may provide an electrical connection path between the second structure PERI and the first structure CELL together with the upper bonding structure 180.

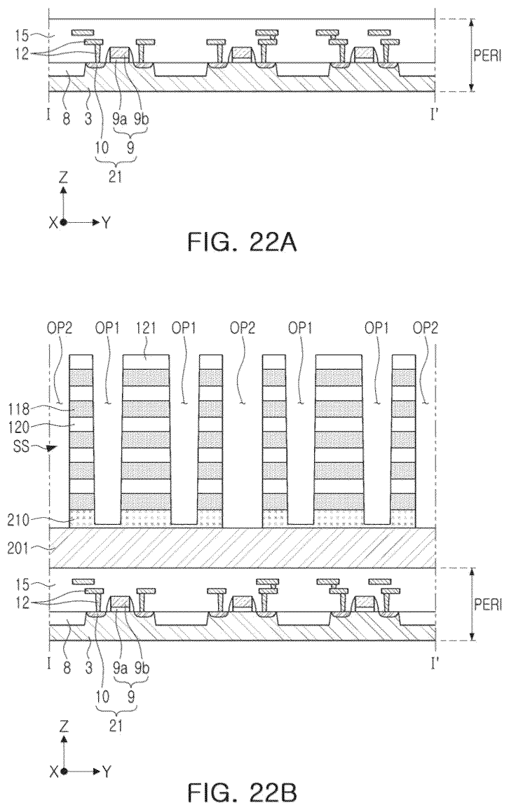

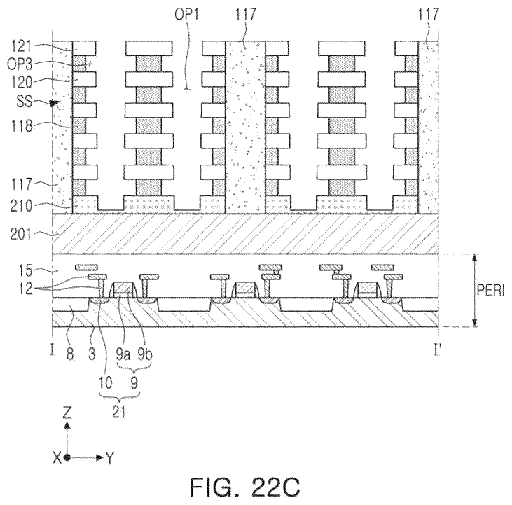

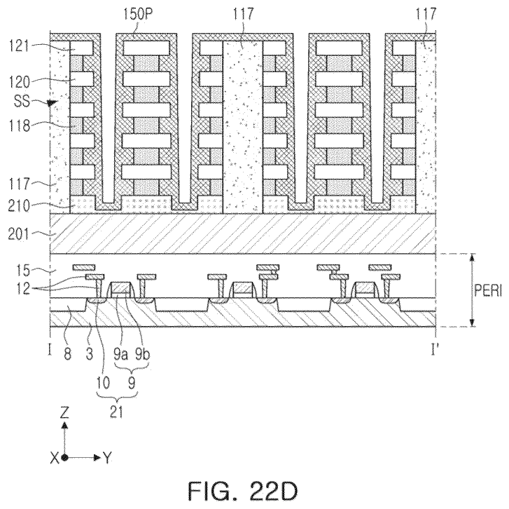

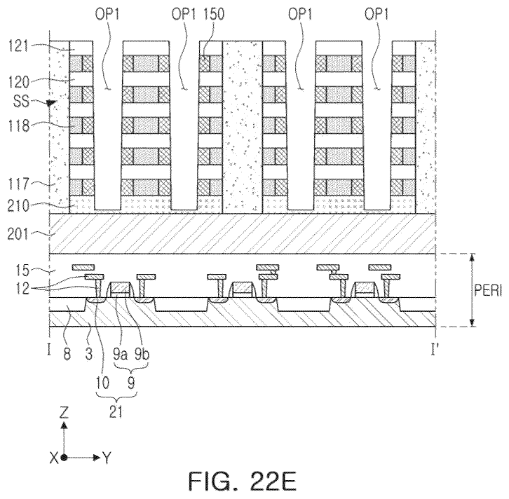

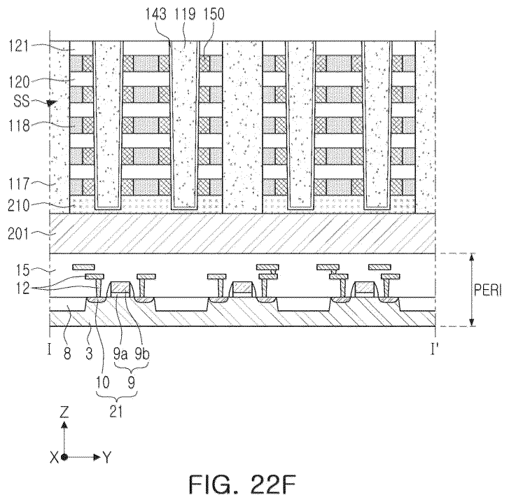

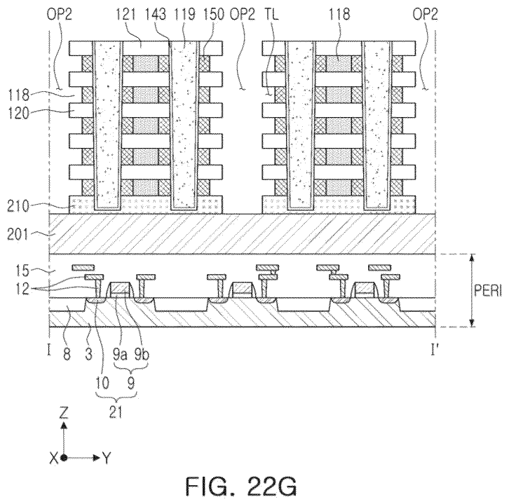

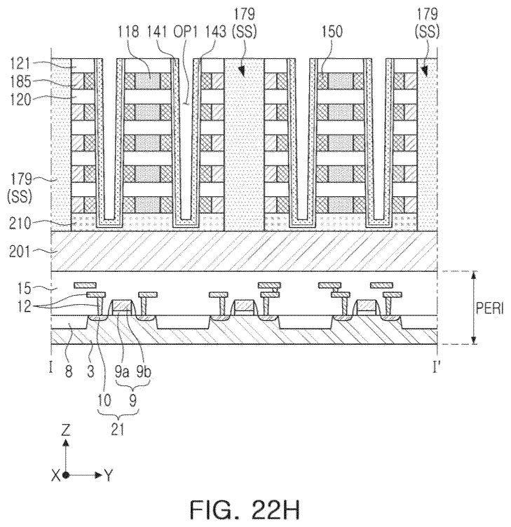

Next, referring to FIGS. 22A to 22H, an example of a method of forming a semiconductor device according to an example embodiment will be described. FIGS. 22A to 22H are cross-sectional views illustrating a region cut along line I-I′ of FIG. 2 to explain an example of a method of forming a semiconductor element according to an example embodiment.

Referring to FIG. 22A, circuit elements 21, a lower interconnection structure 12, a lower bonding structure 18, and a lower capping layer 15, which may be included in a second structure PERI, may be formed on a first substrate 3.

Element isolating layers 8 may be formed in the first substrate 3, and a circuit gate dielectric layer 9b and a circuit gate electrode 9a may be sequentially formed on the first substrate 3. The element isolating layers 8 may be formed, for example, in a shallow trench element isolation (STI) process. The circuit gate dielectric layer 9b may be formed on the first substrate 3, and the circuit gate electrode 9a may be formed on the circuit gate dielectric layer 9b. The circuit gate dielectric layer 9b and the circuit gate electrode 9a may be formed using atomic layer deposition (ALD) or chemical vapor deposition (CVD). The circuit gate dielectric layer 9b may be formed of silicon oxide, and the circuit gate electrode 9a may be formed of at least one of polycrystalline silicon or a metal silicide layer, but the present disclosure is not limited thereto. Spacer layers may be formed on both sidewalls of the circuit gate dielectric layer 9b and the circuit gate electrode 9a, and impurities may be implanted into an active region of the first substrate 3 on both sides of the circuit gate electrode 9a, thus forming source/drain regions 10.

The lower contact plugs among the lower interconnection structures 12 may be formed by forming a portion of the lower capping layer 15, etching and removing the portion, and filling the removed portion with a conductive material. The lower interconnection lines may be formed, for example, by depositing the conductive material thereon and then patterning the conductive material.

The lower capping layer 15 may be formed of a plurality of insulating layers. Accordingly, a second structure PERI may be formed.

Referring to FIG. 22B, a molded structure MS may be formed on the second substrate 201, and vertical holes OP1 for forming vertical structures VS and separation openings OP2 for forming separation structures SS may be formed in the molded structure MS. The second substrate 201 may include a semiconductor material, for example, a group IV semiconductor, a group III-V compound semiconductor, or a group II-VI compound semiconductor.

An etching stop layer 210 may be formed on the second substrate 201. The etching stop layer 210 may include an insulating material, and may be formed by depositing a sacrificial insulating layer 118 and an interlayer insulating layer 120 and an etch-selective material on an entire surface of the second substrate 201. In this case, the etching stop layer 210 may include an oxycarbide, and an oxynitride, but may be implemented as a polymer resin layer. The etching stop layer 210 may have a thickness greater than that of the interlayer insulating layer 120, and may be formed to include the same material as the interlayer insulating layer 120, but the present disclosure is not limited thereto.

The sacrificial insulating layers 118 and the interlayer insulating layers 120 may be alternately stacked on the etching stop layer 210 to form the molded structure MS.

Vertical holes OP1 corresponding to vertical structures VS penetrating through the molded structure MS of the sacrificial insulating layers 118 and the interlayer insulating layers 120 may be formed. In a region corresponding to the separation structure SS (see FIG. 3), separation openings OP2 penetrating through the molded structure MS of the sacrificial insulating layers 118 and the interlayer insulating layers 120 may be formed. The sacrificial insulating layers 118 may be a layer in which a portion thereof is replaced with horizontal electrodes 185 through a subsequent process. An upper interlayer insulating layer 121 may be formed in an upper portion of the sacrificial insulating layers 118 and the interlayer insulating layers 120.

Anisotropic etching may be performed so that a portion of the etching stop layer 210 is etched from the upper interlayer insulating layer 121, thereby forming vertical holes OP1 and separation openings OP2. In this case, the sacrificial insulating layers 118 and the interlayer insulating layers 120 may be sequentially removed using the mask layer to form vertical holes OP1, and a high aspect ratio contact (HARC) etching may be applied thereto depending on a depth thereof. The anisotropic etching may be controlled to proceed only to an upper portion of the etching stop layer 210 or a portion of the etching stop layer 210, and the etching stop layer 210 may not be completely removed and may remain, so that the second substrate 201 in a lower portion may not be exposed.

Accordingly, lower surfaces of the vertical holes OP1 may be disposed in a thickness of the etching stop layer 210. In this case the separation openings OP2 may also be formed, and the separation openings OP2 may be etched to be deeper than the vertical holes OP1 to expose the second substrate 201, but the present disclosure is not limited thereto, and the separation openings OP2 may be formed at the same depth as the vertical holes OP1. As illustrated in FIG. 4, the molded structure MS may be etched to expose the pad region GP having a stepwise shape.

Referring to FIG. 22C, separation sacrificial structures 117 may be formed to fill the separation openings OP2, and some of the sacrificial insulating layers 118 may be removed in the vertical holes OP1.

Specifically, the separation sacrificial structure 117 may include a semiconductor material such as polycrystalline silicon. According to an example embodiment, the separation sacrificial structure 117 may include at least one of silicon oxide, silicon nitride, or silicon oxynitride.

The sacrificial insulating layers 118 exposed to the vertical holes OP1 may be selectively etched to form recessed portions OP3, respectively. Isotropic etching may be performed to remove a portion of the sacrificial insulating layers 118 of each layer in the vertical holes OP1 by applying an etchant that may selectively remove only the sacrificial insulating layers 118 exposed on a side surface inside the vertical holes OP1. Accordingly, the sacrificial insulating layers 118 exposed inside the vertical holes OP1 may be removed from side surfaces of the vertical holes OP1 to a predetermined depth, thus forming the recessed portions OP3.

As illustrated in FIG. 22D, a preliminary second conductive layer 150P forming a second conductive layer 150 forming a protrusion 150 in the vertical holes OP1 may be formed. That is, at least one of polysilicon, a metal, a transition metal, or metal nitride, which may be included in the second conductive layer 150, may fill all of the recessed portions OP3, and may be over-deposited thick enough to cover the side surfaces of each vertical hole OP1.

As illustrated in FIG. 22E, an over-deposited preliminary second conductive layer 150P may be partially isotropically etched until the side surface of the vertical holes OP1 is exposed, thereby forming protrusion portions 150 filling the recessed portions OP3. That is, the preliminary second conductive layer 150P may remain only in the recessed portions OP3, thereby forming the second conductive layers 150 spaced apart from each other in the Z-direction. The etching stop layer 210 below the vertical holes OP1 may be exposed by the partial isotropic etching.

Referring to FIG. 22F, an interface insulating layer 143 may be formed to cover the side surface and the bottom surface of the vertical holes OP1, and an interior of the vertical holes OP1 may be filled to form filled sacrificial structures 119.

The interface insulating layer 143 may be formed by depositing an insulating material over an entire surface thereof, and the insulating material may be conformally deposited at a second thickness T2 to simultaneously cover an inner surface of the second conductive layer 150 and a side surface of the interlayer insulating layer 120.

The filled sacrificial structure 119 may be formed on the interface insulating layer 143 to cover the vertical holes OP1, and may include the same material as the separated sacrificial structure 117, but the present disclosure is not limited thereto.

As in FIG. 6, when the third conductive layer 145 is further included, the recessed portions OP3 may be formed to have a greater depth, and isotropic etching may be performed so that the second conductive layer 150 remains only by a portion of a depth of the recessed portions OP3, and an interface insulating layer 143 may be formed to cover the remaining recessed portions OP3. After the third conductive layer 145 is stacked to cover all of the recessed portions OP3 existing on the interface insulating layers 143, the third conductive layer 145 may be formed to be included in the protrusion portions through partial isotropic etching.

Referring to FIG. 22G, the separation sacrificial structures 117 filling the separation openings OP2 may be removed, and tunnel portions TL may be formed by removing the sacrificial insulating layers 118 by a predetermined depth through the exposed separation openings OP2. A depth of the tunnel portions TL may be adjusted according to the etching time and etchants, and the tunnel portions TL may be formed until the protrusion portions 150 of the vertical structures VS are exposed, specifically, until a portion of the second conductive layer 150 is exposed. Accordingly, the tunnel portions TL from which the sacrificial insulating layers 118 are removed may be formed on one side of the vertical holes OP1 included in the vertical structures VS, and the sacrificial insulating layers 118 may remain on the other side thereof, so that the molded structure MS may be maintained.

As illustrated in FIG. 22H, horizontal electrodes 185 may be formed, and a first information storage layer 141 may be formed in vertical holes OP1.

The tunnel portions TL may be filled with a conductive material through the separation opening OP2 to form horizontal electrodes 185, thereby forming a stack structure GS. A separation insulating layer 179 may be embedded in the separation opening OP2 to form a separation structure SS.

The conductive material may include a metal, polycrystalline silicon, or a metal silicide material. After forming the horizontal electrodes 185, the conductive material deposited in the separation opening OP2 may be removed through an additional process, and then an insulating material may be filled therein to form a separation structure SS.

Then, the filled sacrificial structures 119 may be removed, and a ferroelectric layer forming a first information storage layer 141 may be deposited on the interface insulating layer 143 in the exposed vertical hole OP1. The ferroelectric layer may be deposited at a first thickness T1, and may be conformally formed on the interface insulating layer 143 in the vertical hole OP1, thereby forming the recessed region RS and the protruding region of FIG. 9 according to an example embodiment.

As illustrated in FIG. 3, the first conductive layers 130 may be formed by filling the inside of the vertical holes OP1 with the conductive material on the first information storage layer 141. In an operation of forming the first conductive layers 130, the first conductive layers 130 may be formed by first forming a barrier layer on the side surface and the lower surface of the entire first information storage layer 141 and then filling the inside thereof with a conductive material, but the present disclosure is not limited thereto. According to an example embodiment, the barrier layer may not be formed on the lower surface thereof.

The conductive material may include a metal, polycrystalline silicon, or a metal silicide material.

When the vertical holes OP1 are filled with the first conductive layer 130, vertical structures VS including the first conductive layer 130 and the information storage structure 140 and the protrusion portions 150 may be formed. As illustrated in FIG. 3, the vertical structures VS may be covered, cell region insulating layers 190 may be formed, contact plugs CS may be formed in the extension region R2, and upper interconnection structures 170 and 175 may be formed, thus completing the semiconductor device 100. In the first structure CELL, studs 175 may be formed to be connected to the vertical structures VS and the contact plugs CS, respectively.

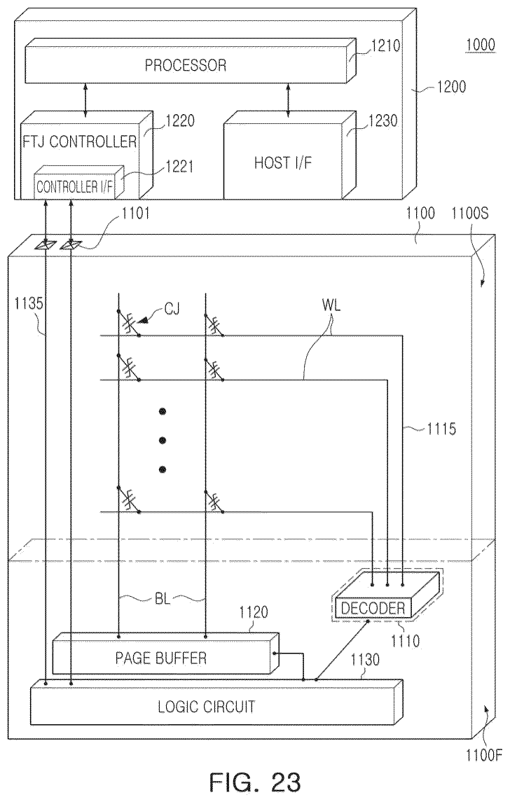

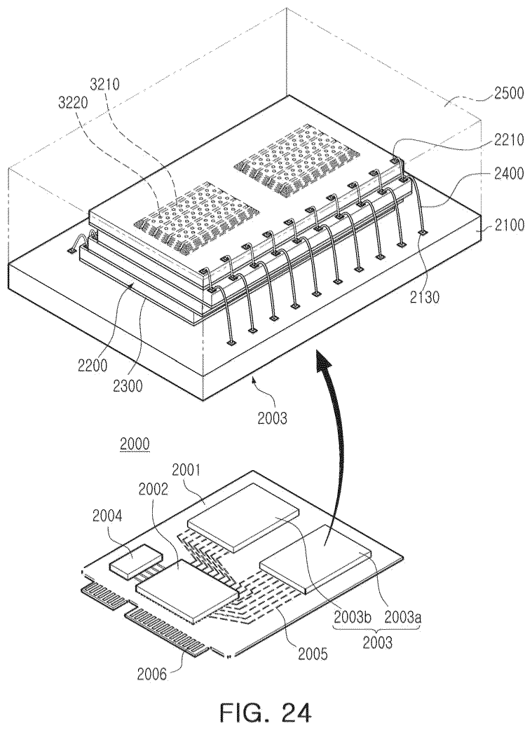

A data storage system including a semiconductor device according to an example embodiment will be described with reference to FIGS. 23 and 24, respectively.

FIG. 23 is a schematic diagram illustrating a data storage system including a semiconductor device according to an example embodiment.

Referring to FIG. 23, a data storage system 1000 according to an example embodiment may include a semiconductor device 1100 and a controller 1200 electrically connected to the semiconductor device 1100 to control the semiconductor device 1100. The data storage system 1000 may be a storage device including the semiconductor device 1100 or an electronic device including the storage device. For example, the data storage system 1000 may be a solid state drive device (SSD), a Universal Serial Bus (USB), a computing system, a medical device, or a communication device, which include the semiconductor device 1100.

In an example embodiment, the data storage system 1000 may be an electronic system that stores data.

The semiconductor device 1100 may be a nonvolatile memory device. For example, the semiconductor device 1100 may be a semiconductor device consistent with the description above with reference to FIGS. 1 to 21. The semiconductor device 1100 may include a first structure 1100F and a second structure 1100S on the first structure 1100F.

The first structure 1100F may be a peripheral circuit structure including a decoder circuit 1110, a page buffer 1120, and a logic circuit 1130. For example, the first structure 1100F may include the peripheral circuit structure PERI (see FIG. 3) described above. The above-described peripheral circuit 21 (see FIG. 3) may be a transistor including a decoder circuit 1110, a page buffer 1120, and a logic circuit 1130.

The second structure 1100S may be a memory structure including a bit line BL, word lines WL, and memory cell strings CJS between the bit lines BL and the word lines WL.

In the second structure 1100S, each of the memory cell strings CJS may include ferroelectric tunnel junctions FTJ disposed between the bit lines BL and the word lines WL as unit memory cells CJ. The number of unit memory cells CJ may be variously modified according to example embodiments.

As described in FIG. 3, the plurality of ferroelectric tunnel junctions FTJ may include first and second conductive layers 130 and 150 respectively connected to word lines WL and bit lines BL, and a first information storage layer 141 and an interface insulating layer 143 having a ferroelectric between the first and second conductive layers 130 and 150.

The word lines WL may be electrically connected to the decoder circuit 1110 through first interconnection lines 1115 extending from the first structure 1100F to the second structure 1100S.

The bit lines BL may be electrically connected to the page buffer 1120 through second interconnection lines 1125 extending from the first structure 1100F to the second structure 1100S.

In the first structure 1100F, the decoder circuit 1110 and the page buffer 1120 may execute a control operation for at least one memory cell CJ, among the memory cells CJ. The decoder circuit 1110 and the page buffer 1120 may be controlled by a logic circuit 1130.

The semiconductor device 1000 may further include an input/output pad 1101. The semiconductor device 1000 may communicate with the controller 1200 through the input/output pad 1101 electrically connected to the logic circuit 1130. The input/output pad 1101 may be electrically connected to the logic circuit 1130 through an input/output interconnection line 1135 extending from the first structure 1100F to the second structure 1100S. Accordingly, the controller 1200 may be electrically connected to the semiconductor device 1000 through the input/output pad 1101, and may control the semiconductor device 1000.

The controller 1200 may include a processor 1210, an FTJ controller 1220, and a host interface 1230. According to example embodiments, the data storage system 1000 may include a plurality of semiconductor devices 1100, and in this case, the controller 1200 may control the plurality of semiconductor devices 1000.

The processor 1210 may control an overall operation of the data storage system 1000 including the controller 1200. The processor 1210 may operate according to a predetermined firmware, and may control the FTJ controller 1220 to access the semiconductor device 1100. The FTJ controller 1220 may include an FTJ interface 1221 processing communication with the semiconductor device 1100. Through the FTJ interface 1221, a control command for controlling the semiconductor device 1100, data to be recorded in the ferroelectric tunnel junctions (FTJ) of the semiconductor device 1100, data to be read from the memory cell CJ of the semiconductor device 1100, or the like, may be transmitted. The host interface 1230 may provide a communication function between the data storage system 1000 and an external host. When the control command is received from the external host through the host interface 1230, the processor 1210 may control the semiconductor device 1100 in response to the control command.

FIG. 24 is a perspective view schematically illustrating a data storage system including a semiconductor device according to an example embodiment.

Referring to FIG. 24, a data storage system 2000 according to an example embodiment may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to the external host. The number and arrangement of the plurality of pins in the connector 2006 may vary depending on a communication interface between the data storage system 2000 and the external host. In example embodiments, the data storage system 2000 may communicate with an external host according to any one of interfaces such as USB, Peripheral Component Interconnect Express (PCI-Express), Serial Advanced Technology Attachment (SATA), and M-Phy for Universal Flash Storage (UFS). In example embodiments, the data storage system 2000 may operate by power supplied from the external host through the connector 2006. The data storage system 2000 may further include a Power Management Integrated Circuit (PMIC) configured to distribute power supplied from the external host to the controller 2002 and the semiconductor package 2003.

The controller 2002 may record data in the semiconductor package 2003 or read data from the semiconductor package 2003, and may improve the operating speed of the data storage system 2000.

The DRAM 2004 may be a buffer memory for mitigating a speed difference between the semiconductor package 2003, which is a data storage space, and the external host. The DRAM 2004 included in the data storage system 2000 may also function as a type of cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the FTJ controller for controlling the semiconductor package 2003.

The semiconductor package 2003 may include first and second semiconductor packages 2003a and 2003b spaced apart from each other. The first and second semiconductor packages 2003a and 2003b may each be a semiconductor package including a plurality of semiconductor chips 2200. Each of the semiconductor chips 2200 may include a semiconductor device consistent with the description above with reference to FIGS. 1 to 21.

Each of the first and second semiconductor packages 2003a and 2003b may include a package substrate 2100, semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210.

In example embodiments, the connection structure 2400 may be a bonding wire that electrically connects the input/output pad 2210 and the package upper pads 2130. Accordingly, in each of the first and second semiconductor packages 2003a and 2003b, the semiconductor chips 2200 may be electrically connected to each other in a bonding wire manner, and may be electrically connected to the package upper pads 2130 of the package substrate 2100. According to example embodiments, in each of the first and second semiconductor packages 2003a and 2003b, the semiconductor chips 2200 may be electrically connected to each other by a connection structure including a through-silicon via (TSV), instead of the connection structure 2400 in a bonding wire manner.

In example embodiments, the controller 2002 and the semiconductor chips 2200 may be included in a single package. For example, the controller 2002 and the semiconductor chips 2200 may be mounted on a separate interposer substrate different from the main substrate 2001, and the controller 2002 and the semiconductor chips 2200 may be connected to each other by interconnection lines formed on the interposer substrate.

In this specification, the first signal lines (S11, S12, . . . ) are described as bit lines, and the second signal lines (S21, S22, . . . , S2n) are described as word lines, but the first signal lines (S11, S12, . . . ) and the second signal lines (S21, S22, . . . , S2n) are conductive signal lines for applying voltage to each unit memory cell CJ, and are not limited to names thereof, and on the contrary, the first signal lines (S11, S12, . . . ) may be referred to as word lines, and the second signal lines (S21, S22, . . . , S2n) may be referred to as bit lines.

While aspects of example embodiments have been particularly shown and described, it will be understood that various changes in form and details may be made therein without departing from the spirit and scope of the following claims.

What is claimed is:

1. A semiconductor device, comprising:
stack structures comprising interlayer insulating layers and horizontal electrodes alternately stacked on a substrate in a vertical direction, the stack structures extending in a first direction, perpendicular to the vertical direction, and spaced apart from each other in a second direction, perpendicular to the first direction;
a molded structure comprising the interlayer insulating layers and sacrificial insulating layers alternately stacked on the substrate in the vertical direction, the molded structure extending in the first direction between the stack structures;
vertical pillars provided in holes penetrating through the stack structures and the molded structure at boundaries between the stack structures and the molded structure, and spaced apart from the substrate; and
protrusion portions provided between each of the vertical pillars and the horizontal electrodes, and spaced apart from each other in the vertical direction,
wherein each of the vertical pillars comprises:
a conductive pillar provided in a hole;
a first information storage layer covering a side surface and a bottom surface of the conductive pillar, and comprising a ferroelectric layer; and
an interface insulating layer covering an outer surface of the first information storage layer, and
wherein each of the protrusion portions comprises a conductive layer in which a portion of an outer surface of the conductive layer is in contact with one of the horizontal electrodes, and a remainder of the outer surface of the conductive layer is in contact with one of the sacrificial insulating layers.

2. The semiconductor device of claim 1, wherein a thickness of the first information storage layer in a horizontal direction perpendicular to the vertical direction, is greater than a thickness of the interface insulating layer.

3. The semiconductor device of claim 1, wherein a radius of the conductive pillar along the first direction is equal to or less than a thickness of the first information storage layer along the first direction.

4. The semiconductor device of claim 1, wherein the conductive pillar and the conductive layer comprise different materials.

5. The semiconductor device of claim 1, wherein the conductive pillar includes a metallic material, and the conductive layer comprises a semiconductor material.

6. The semiconductor device of claim 1, wherein each of the vertical pillars comprises:
a second information storage layer between the conductive pillar and the first information storage layer; and
a first insulating layer between the conductive pillar and the second information storage layer, and
wherein the second information storage layer is a charge trapping layer.

7. The semiconductor device of claim 1, wherein each of the protrusion portions further comprises a floating electrode between the first information storage layer and the conductive layer.

8. The semiconductor device of claim 7, wherein the interface insulating layer extends between the conductive layer and the floating electrode from portions between the interlayer insulating layers and the first information storage layer, and wherein the conductive layer and the floating electrode are spaced apart from each other by the interface insulating layer.

9. The semiconductor device of claim 1, wherein the outer surface of the first information storage layer comprises a protruding region protruding outwardly toward the protrusion portions, and an inner surface of the first information storage layer comprises a recessed region in a region corresponding to the protruding region.

10. The semiconductor device of claim 1, wherein each of the conductive pillar and the conductive layer comprises at least one of a metallic material, a metal nitride, a semiconductor material, or an intermetallic compound.

11. The semiconductor device of claim 1, further comprising an etching stop layer comprising an insulating material between the substrate and the stack structures,
wherein the vertical pillars are spaced apart from the substrate by the etching stop layer.

12. The semiconductor device of claim 1, further comprising:
a first conductive line on the stack structures; and
a stud electrically connecting the first conductive line and the conductive pillar between the first conductive line and the conductive pillar.

13. A semiconductor device, comprising:
a stack structure comprising interlayer insulating layers and horizontal electrodes alternately stacked on a substrate in a vertical direction, the stack structure extending in a first direction, perpendicular to the vertical direction;
a molded structure comprising the interlayer insulating layers and sacrificial insulating layers alternately stacked on the substrate in the vertical direction, and provided adjacent to the stack structure in a second direction, and extending in the first direction, the second direction being perpendicular to the vertical direction and the first direction; and
vertical structures provided in holes penetrating through the stack structure and the molded structure at boundaries between the stack structure and the molded structure, and spaced apart from the substrate,
wherein each of the vertical structures comprises:
a conductive pillar provided in a central region of each of the holes;
a first information storage layer surrounding the conductive pillar, having a first thickness, and comprising a ferroelectric layer;
an interface insulating layer surrounding the first information storage layer, having a second thickness less than the first thickness; and
conductive layers surrounding the interface insulating layer between the interface insulating layer and the horizontal electrodes, the conductive layers being spaced apart from each other in the vertical direction.

14. The semiconductor device of claim 13, wherein each of the horizontal electrodes is in contact with ½ or less of an outer surface of each of the conductive layers.

15. The semiconductor device of claim 13, wherein the conductive pillar penetrates through a hole,
wherein the first information storage layer and the interface insulating layer surround the conductive pillar and extend continuously in the vertical direction, and
wherein the conductive layers surround the interface insulating layer on different levels along the vertical direction and each of the conductive layers forms a ring and is separated from other layers of the conductive layers.

16. The semiconductor device of claim 13, wherein the first information storage layer comprises an inner surface in contact with the conductive pillar and an outer surface in contact with the interface insulating layer, and
wherein an area of the inner surface is less than an area of the outer surface.

17. The semiconductor device of claim 13, wherein a radius of the conductive pillar is equal to or less than the first thickness of the first information storage layer.

18. The semiconductor device of claim 13, wherein the stack structure comprises:
a first region in which the vertical structures are provided; and
a second region which extends in the first direction along with the first region, and comprises contact structures connected to each of the horizontal electrodes, and
wherein in the first region, conductive pillars of the vertical structures are connected to first signal lines, and in the second region, the contact structures are connected to second signal lines.

19. The semiconductor device of claim 18, wherein a width of the stack structure in the second direction in the first region is less than a width of the stack structure in the second direction in the second region.

20. A data storage system, comprising:
a semiconductor device comprising an input/output pad; and
a controller electrically connected to the semiconductor device through the input/output pad and configured to control the semiconductor device,
wherein the semiconductor device comprises:
stack structures comprising interlayer insulating layers and horizontal electrodes alternately stacked on a substrate in a vertical direction, the stack structures extending in a first direction, perpendicular to the vertical direction, and the stack structures being spaced apart from each other in a second direction, perpendicular to the first direction;
a molded structure comprising the interlayer insulating layers and sacrificial insulating layers alternately stacked on the substrate in the vertical direction, and extending in the first direction between the stack structures;
vertical pillars provided in holes penetrating through the stack structures and the molded structure, and spaced apart from the substrate; and
protrusion portions provided between each of the vertical pillars and the horizontal electrodes at boundaries between the stack structures and the molded structure, and spaced apart from each other in the vertical direction,
wherein each of the vertical pillars comprises:
a conductive pillar provided in a hole;
a first information storage layer covering a side surface and a bottom surface of the conductive pillar, and comprising a ferroelectric layer; and
an interface insulating layer covering an outer surface of the first information storage layer, and
wherein each of the protrusion portions comprises a conductive layer in which a first portion of an outer surface of the conductive layer is in contact with one of the horizontal electrodes and a second portion of the outer surface of the conductive layer is in contact with one of the sacrificial insulating layers.
